(19) United States
(12) Patent Application Publication
(10) Pub. No.: US 2020/0089115 A1
(43) Pub. Date: Mar. 19, 2020

(54) MONOMERS, PHOTORESIST RESINS, PHOTORESIST RESIN COMPOSITIONS, AND PATTERN FORMING METHOD

(71) Applicant: DAICEL CORPORATION, Osaka (JP)

(72) Inventors: Akira Eguchi, Tokyo (JP); Kazuhiro Uehara, Tokyo (JP); Takashi Maruyama, Tokyo (JP)

(73) Assignee: DAICEL CORPORATION, Osaka (JP)

(21) Appl. No.: 16/569,305

(22) Filed: Sep. 12, 2019

(30) Foreign Application Priority Data
Sep. 13, 2018 (JP) 2018-171550

(51) Int. Cl. G03F 7/039; C08F 20/28; G03F 7/004

(52) U.S. Cl. CPC G03F 7/0392; G03F 7/0045; C08F 20/28

(57) ABSTRACT

Object:

To provide a monomer that is useful in forming a photoresist resin that has excellent swelling resistance.

Resolution Means:

A photoresist resin containing a polymerization unit represented by Formula (Y),
where R^{X} denotes a halogen atom or an alkyl group having from 1 to 6 carbon atoms substituted with a halogen atom; A¹ denotes a single bond or a linking group, and when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

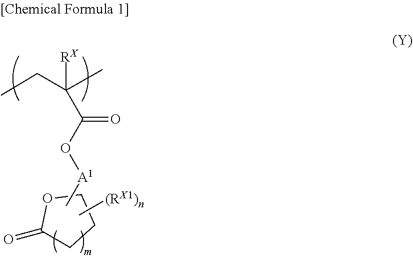

### TECHNICAL FIELD

The present invention relates to monomers, resins, resin compositions, and a pattern forming method. This application claims priority to Japanese Patent Application No. 2018-171550, filed to Japan on Sep. 13, 2018, the entire contents of which are incorporated herein by reference.

### BACKGROUND ART

In the manufacturing of semiconductors, significant innovations are being made in lithographic techniques for pattern formation. Initially, the i-line and g-line were used for exposure in lithography, and pattern line widths were wide, and therefore the capacity of semiconductors that were produced was low. However, recent developments in technology have enabled the use of a KrF excimer laser of a short wavelength and an ArF excimer laser of an even shorter wavelength, and the pattern line width is rapidly reduced.

For exposure using a KrF excimer laser, a novolac or styrene-based resin has been used, but the resin contains an aromatic group, and causes a problem of absorption of the laser light from the ArF excimer laser. Therefore, for exposure using an ArF excimer laser, a resin that does not contain an aromatic group (e.g., a resin having an alicyclic skeleton) is used instead of a resin that contains an aromatic group. The resins that are used for exposure using an ArF excimer laser are mainly acrylic resins. The use of such resins is motivated by application of the following mechanism: when a resin composition that contains: an acrylic resin containing a (meth)acrylic acid protected by a protecting group as a monomer unit, and a radiation sensitive acid generating agent, is used, an acid generated by the exposure eliminates the protecting group in the monomer unit to form a carboxyl group, and thus the resin becomes soluble in an alkaline solution.

Although many of the protecting groups that are currently used are groups having a non-polar alicyclic skeleton, such protecting groups exhibit poor adhesion to a substrate and lack affinity to alkaline developing solutions. Thus, numerous proposals have been made for acrylic monomers having a polar alicyclic skeleton (e.g., those having an ester group). Among these, an alicyclic skeleton having a lactone ring has been found to exhibit high functionality, and numerous such alicyclic skeletons are being used (Patent Documents 1 and 2).

In addition, narrower pattering demands further improvements in line width variation called line width roughness (hereinafter “LWR”) in a formed pattern. One cause of a deterioration in LWR is swelling of the pattern due to the alkaline developing solution, and as a method for solving this problem, a method of using a resin containing a specific tertiary ester unit having a cyclic ether structure has been proposed (Patent Document 3).

### CITATION LIST

### Patent Documents

Patent Document 1: JP 2000-026446 A

Patent Document 2: JP 10-274852 A

Patent Document 3: WO 2007/094473

### SUMMARY OF INVENTION

### Technical Problem

However, the resin described above does not possess sufficient swelling resistance (a property of suppressing swelling of the pattern due to the alkaline developing solution), and thus further improvements are in demand.

Therefore, an object of the present invention is to provide monomers that are useful for forming a resin that has good swelling resistance. Another object of the present invention is to provide a resin that has good swelling resistance and a resin composition containing the resin. Yet another object of the present invention is to provide a method that can achieve excellent swelling resistance and form a fine pattern with good precision by using the resin composition.

### Solution to Problem

As a result of diligent research to achieve the object described above, the present inventors discovered that use of a resin containing polymerization units having a specific structure improves swelling resistance. The present invention was completed based on these findings.

Namely, the present invention provides a resin containing a polymerization unit represented by Formula (Y):

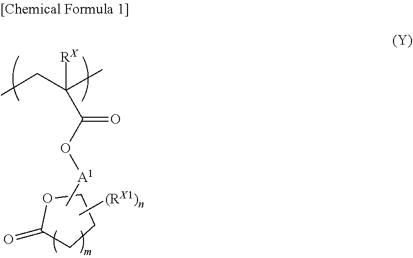

where R^{X} denotes a halogen atom or an alkyl group having from 1 to 6 carbon atoms substituted with a halogen atom; A¹ denotes a single bond or a linking group, and when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

The resin preferably contains at least one polymerization unit selected from the group consisting of a polymerization unit represented by Formula (Y1):

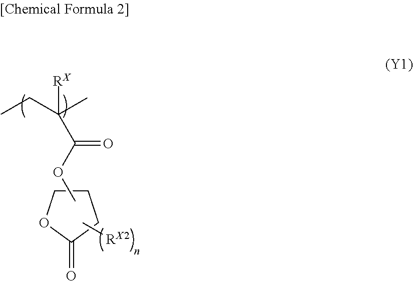

where R^{X} denotes a halogen atom or an alkyl group having from 1 to 6 carbon atoms substituted with a halogen atom; R^{X2} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X2} may be the same or different and may be bonded to each other to form a ring; and

a polymerization unit represented by Formula (Y2):

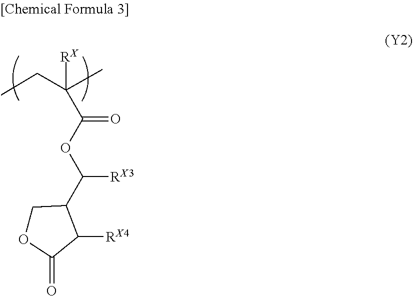

where R^{X} denotes a halogen atom or an alkyl group having from 1 to 6 carbon atoms substituted with a halogen atom; R^{X3} and R^{X4} may be the same or different, and denote a hydrogen atom, an alkyl group having from 1 to 6 carbon atoms, or an alkenyl group having from 2 to 6 carbon atoms, and R^{X3} and R^{X4} may be bonded to each other to form a ring.

The resin preferably contains at least one polymerization unit selected from the group consisting of polymerization units represented by Formulas (a1) to (a4):

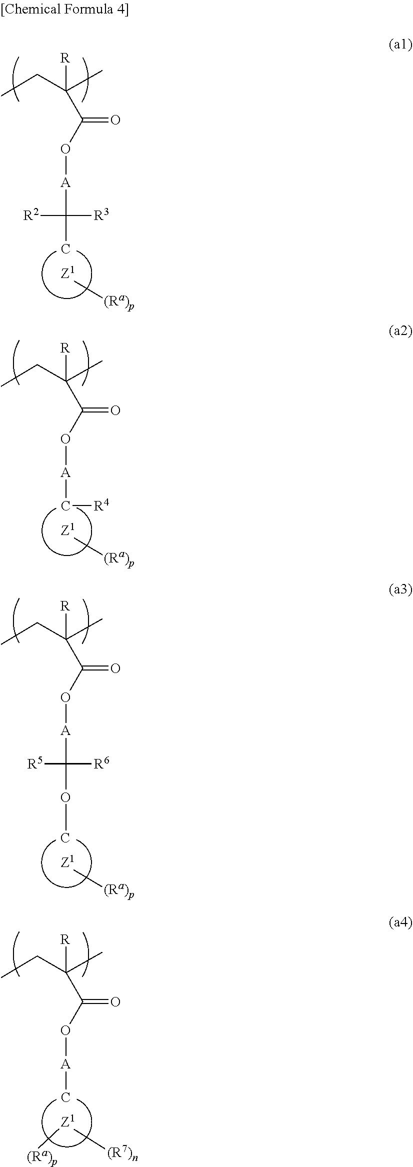

where R denotes a hydrogen atom, a halogen atom, or an alkyl group which has from 1 to 6 carbon atoms and may have a halogen atom; A denotes a single bond or a linking group; R² to R⁴ may be the same or different and denote an alkyl group which has from 1 to 6 carbon atoms and may have a substituent; R² and R³ may be bonded to each other to form a ring; R⁵ and R⁶ may be the same or different and denote a hydrogen atom or an alkyl group which has from 1 to 6 carbon atoms and may have a hydrogen atom or a substituent; R⁷ denotes a —COOR^{c} group, and the R^{c} denotes a tertiary hydrocarbon group, a tetrahydrofuranyl group, a tetrahydropyranyl group, or an oxepanyl group, each of which may have a substituent; n denotes an integer from 1 to 3; R^{a} is a substituent bonded to a ring Z¹, and may be the same or different, and denotes an oxo group, an alkyl group, a hydroxy group that may be protected by a protecting group, a hydroxyalkyl group that may be protected by a protecting group, or a carboxy group that may be protected by a protecting group; p denotes an integer from 0 to 3; and the ring Z¹ denotes an alicyclic hydrocarbon ring having from 3 to 20 carbon atoms.

The resin preferably contains at least one polymerization unit selected from the group consisting of polymerization units represented by Formulas (b1) to (b5) (excluding polymerization units corresponding to the polymerization unit represented by Formula (Y)):

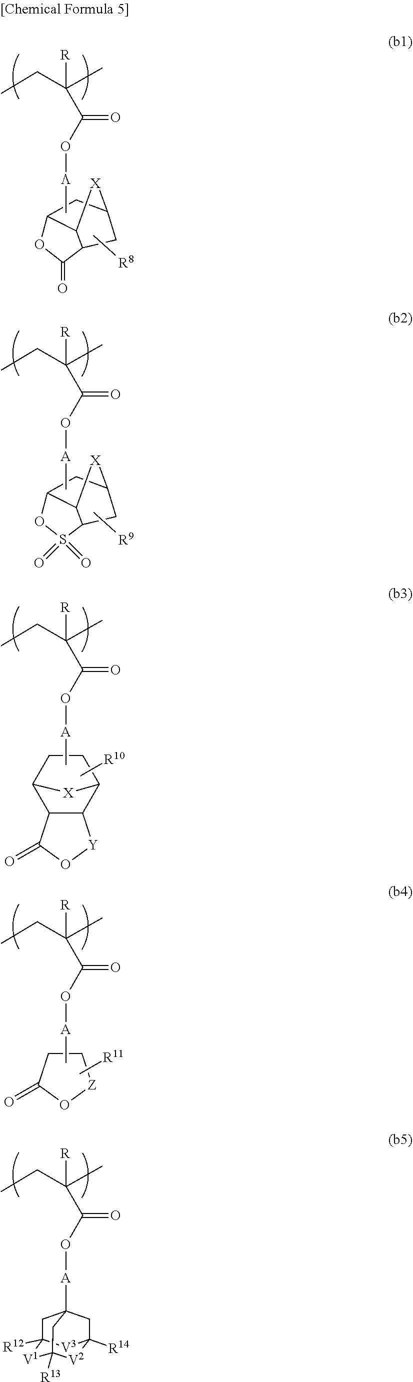

where R denotes a hydrogen atom, a halogen atom, or an alkyl group which has from 1 to 6 carbon atoms and may have a halogen atom; A denotes a single bond or a linking group; X denotes no bond, a methylene group, an ethylene group, an oxygen atom, or a sulfur atom; Y denotes a methylene group or a carbonyl group; Z denotes a divalent organic group; V¹ to V³ may be the same or different, and denote —CH₂—, [—C(═O)—], or [—C(═O)—O—], with a proviso that at least one of V¹ to V³ is [—C(═O)—O—]; and R⁸ to R¹⁴ may be the same or different, and denote a hydrogen atom, a fluorine atom, an alkyl group that may have a fluorine atom, a hydroxy group that may be protected by a protecting group, a hydroxyalkyl group that may be protected by a protecting group, a carboxy group that may be protected by a protecting group, or a cyano group.

The resin preferably contains a polymerization unit represented by Formula (c1):

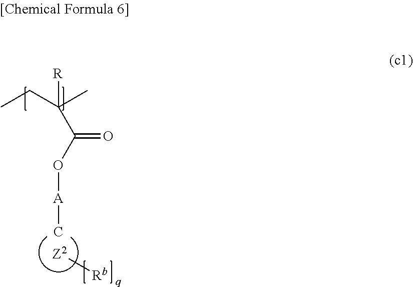

where R denotes a hydrogen atom, a halogen atom, or an alkyl group which has from 1 to 6 carbon atoms and may have a halogen atom; A denotes a single bond or a linking group; R^{b} denotes a hydroxy group that may be protected by a protecting group, a hydroxyalkyl group that may be protected by a protecting group, a carboxy group that may be protected by a protecting group, or a cyano group; q denotes an integer from 1 to 5; and the ring Z² denotes an alicyclic hydrocarbon ring having from 6 to 20 carbon atoms.

The present invention also provides a resin composition containing at least the resin and a radiation sensitive acid generating agent.

The present invention also provides a pattern forming method including at least applying the composition to a substrate to form a coating film, exposing the coating film, and then subjecting the coating film to alkali dissolution.

The present invention also provides a monomer represented by Formula (X):

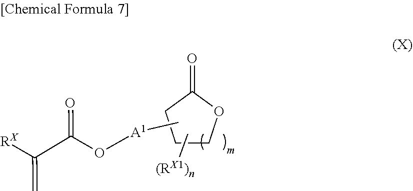

where R^{X} denotes a halogen atom or an alkyl group having from 1 to 6 carbon atoms substituted with a halogen atom; A¹ denotes a single bond or a linking group, and when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

The monomer is preferably a monomer represented by Formula (X1):

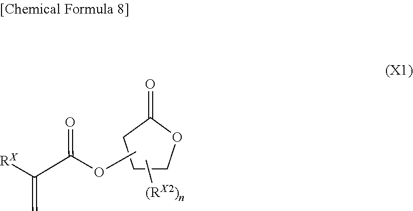

where R^{X} denotes a halogen atom or an alkyl group having from 1 to 6 carbon atoms substituted with a halogen atom; R^{X2} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X2} may be the same or different and may be bonded to each other to form a ring;

or a monomer represented by Formula (X2):

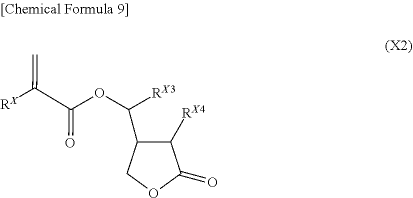

where R^{X} denotes a halogen atom or an alkyl group having from 1 to 6 carbon atoms substituted with a halogen atom; R^{X3} and R^{X4} may be the same or different, and denote a hydrogen atom, an alkyl group having from 1 to 6 carbon atoms, or an alkenyl group having from 2 to 6 carbon atoms, and R^{X3} and R^{X4} may be bonded to each other to form a ring.

### Advantageous Effects of the Invention

According to the present invention, a monomer useful for forming a resin that has good swelling resistance is provided. Additionally, a resin having good swelling resistance and a resin composition containing the resin are provided. Also provided is a method capable of achieving excellent swelling resistance and forming with good precision a fine pattern f by using the resin composition.

### DESCRIPTION OF EMBODIMENTS

### Monomer

The monomer of an embodiment of the present invention is represented by Formula (X).

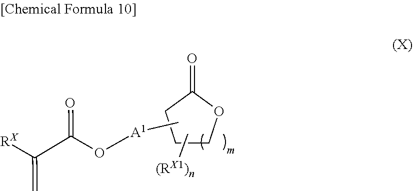

In Formula (X), R^{X} denotes a halogen atom or an alkyl group having from 1 to 6 carbon atoms substituted with a halogen atom; A¹ denotes a single bond or a linking group; when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

The halogen atom in R^{X} is not particularly limited, but from the viewpoint of improving swelling resistance, a fluorine atom and a chlorine atom are preferable, and a fluorine atom is more preferable. In addition, the number of carbon atoms of the alkyl group in R^{X} is not particularly limited as long as the number is from 1 to 6, but is preferably from 1 to 3, and more preferably 1 or 2. That is, from the viewpoint of improving swelling resistance, the alkyl group having from 1 to 6 carbon atoms substituted with a halogen atom in R^{X} is preferably an alkyl group having 1 or 2 carbon atoms substituted with a fluorine atom, such as a fluoromethyl group, a difluoromethyl group, a trifluoromethyl group, a 2,2,2-trifluoroethyl group, and a 1,1,2,2,2-pentafluoroethyl group, and is more preferably a trifluoromethyl group.

Note that, with respect to the monomer represented by Formula (X), the reason that the swelling resistance improves is not clear, but it is thought that when R^{X} is a halogen atom or an alkyl group having from 1 to 6 carbon atoms substituted with a halogen atom, the water repellency of the resin containing a polymerization unit derived from the monomer described above (that is, a polymerization unit represented by Formula (Y)) improves, and as a result, the alkaline developing solution becomes less likely to permeate into the resin film, and swelling of the pattern is suppressed.

The number of carbon atoms of the alkyl group in R^{X1} is not particularly limited as long as the number is from 1 to 6, but is, for example, preferably from 1 to 4. The number of carbon atoms of the alkenyl group in R^{X1} is not particularly limited as long as the number is from 2 to 6, but is, for example, preferably from 2 to 4. When n is 2 or greater and the multiple R^{X1} are mutually bonded to form a ring, the multiple R^{X1} may form a ring via an oxygen atom or a sulfur atom. Furthermore, the carbon atoms constituting the ring may form a double bond with an adjacent carbon atom. Note that the number of carbon atoms constituting the ring is not particularly limited, but is preferably from 4 to 12, more preferably from 4 to 10, and even more preferably from 4 to 6.

Examples of the linking group in A¹ include alkylene groups, a carbonyl group (—C(═O)—), an ether bond (—O—), an ester bond (—C(═O)—O—), an amide bond (—C(═O)—NH—), a carbonate bond (—O—C(═O)—O—), and groups in which a plurality of these are linked together. Examples of the alkylene group include straight or branched chain alkylene groups such as methylene, methylmethylene, dimethylmethylene, ethylene, propylene, and trimethylene groups; and divalent alicyclic hydrocarbon groups (particularly divalent cycloalkylene groups) such as 1,2-cyclopentylene, 1,3-cyclopentylene, cyclopentylidene, 1,2-cyclohexylene, 1,3-cyclohexylene, 1,4-cyclohexylene, and cyclohexylidene groups. When A¹ is bonded to the α position of a lactone ring, the adhesion of the resin to the substrate tends to improve.

When A¹ and R^{X1} are bonded to each other to form a ring, the ring may be formed via an oxygen atom or a sulfur atom. Furthermore, the carbon atoms constituting the ring may form a double bond with an adjacent carbon atom. Note that the number of carbon atoms constituting the ring is not particularly limited, but is preferably from 4 to 12, more preferably from 4 to 10, and even more preferably from 4 to 6.

The monomer of an embodiment of the present invention is not particularly limited, and examples thereof include monomers represented by Formulas (X1) and (X2).

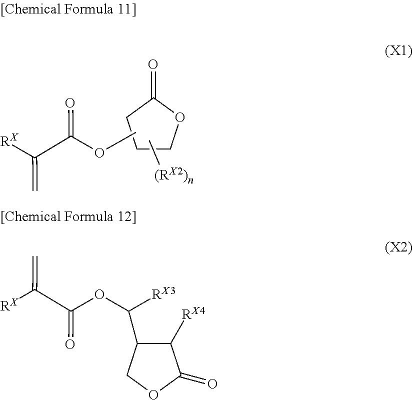

In Formula (X1), R^{X} is the same as that described with regard to Formula (X), and denotes a halogen atom or an alkyl group having from 1 to 6 carbon atoms substituted with a halogen atom. R^{X2} denotes a hydrogen atom, an alkyl group having from 1 to 6 carbon atoms, or an alkenyl group having from 2 to 6 carbons. n denotes an integer from 0 to 5. When n is 2 or greater, the multiple R^{X2} may be the same or different and may be bonded to each other to form a ring.

The number of carbon atoms in the alkyl group in R^{X2} is not particularly limited as long as the number is from 1 to 6, but is, for example, preferably from 1 to 4. The number of carbon atoms of the alkenyl group in R^{X2} is not particularly limited as long as the number is from 2 to 6, but is, for example, preferably from 2 to 4. When multiple R^{X2} are bonded to each other to form a ring, the R^{X2} may form a ring through an oxygen atom or a sulfur atom. Furthermore, the carbon atoms constituting the ring may form a double bond with an adjacent carbon atom. Note that the number of carbon atoms constituting the ring is not particularly limited, but is preferably from 4 to 12, more preferably from 4 to 10, and even more preferably from 4 to 6.

In Formula (X2), R^{X} is the same as that described with regard to Formula (X), and denotes a halogen atom or an alkyl group having from 1 to 6 carbon atoms substituted with a halogen atom. R^{X3} and R^{X4} may be the same or different, and denote a hydrogen atom, an alkyl group having from 1 to 6 carbon atoms, or an alkenyl group having from 2 to 6 carbon atoms, and

R^{X3} and R^{X4} may be bonded to each other to form a ring.

The number of carbon atoms in the alkyl groups in R^{X3} and R^{X4} is not particularly limited as long as the number is from 1 to 6, but is, for example, preferably from 1 to 4. The number of carbon atoms of the alkenyl groups in R^{X3} and R^{X4} is not particularly limited as long as the number is from 2 to 6, but is, for example, preferably from 2 to 4. When R^{X3} and R^{X4} are bonded to each other to form a ring, R^{X3} and R^{X4} may form a ring via an oxygen atom or a sulfur atom. Furthermore, the carbon atoms constituting the ring may form a double bond with an adjacent carbon atom. Note that the number of carbon atoms constituting the ring is not particularly limited, but is preferably from 4 to 12, more preferably from 4 to 10, and even more preferably from 4 to 6.

The monomer represented by Formula (X1) is not particularly limited, and examples thereof include monomers represented by Formula (X3) and Formula (X4).

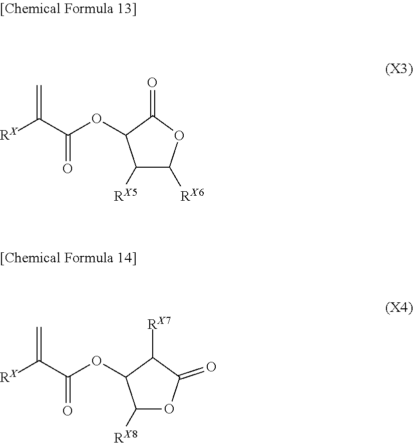

In Formula (X3), R^{X} is the same as that described with regard to Formula (X), and denotes a halogen atom or an alkyl group having from 1 to 6 carbon atoms substituted with a halogen atom. R^{X5} and R^{X6} may be the same or different, and denote a hydrogen atom, an alkyl group having from 1 to 6 carbon atoms, or an alkenyl group having from 2 to 6 carbon atoms, and R^{X5} and R^{X6} may be bonded to each other to form a ring. The number of carbon atoms in the alkyl groups in R^{X5} and R^{X6} is not particularly limited as long as the number is from 1 to 6, but is, for example, preferably from 1 to 4, and more preferably from 1 to 2. Moreover, the number of carbon atoms of the alkenyl group is not particularly limited as long as the number is from 2 to 6, but is, for example, preferably from 2 to 4.

In Formula (X4), R^{X} is the same as that described with regard to Formula (X), and denotes a halogen atom or an alkyl group having from 1 to 6 carbon atoms substituted with a halogen atom. R^{X7} and R^{X8} may be the same or different, and denote a hydrogen atom, an alkyl group having from 1 to 6 carbon atoms, or an alkenyl group having from 2 to 6 carbon atoms.

The number of carbon atoms in the alkyl groups in R^{X5} and R^{X6} is not particularly limited as long as the number is from 1 to 6, but is, for example, preferably from 1 to 4, and more preferably from 1 to 2. Moreover, the number of carbon atoms of the alkenyl group is not particularly limited as long as the number is from 2 to 6, but is, for example, preferably from 2 to 4.

Representative examples of monomers represented by Formula (X) include monomers represented by the following formulas.

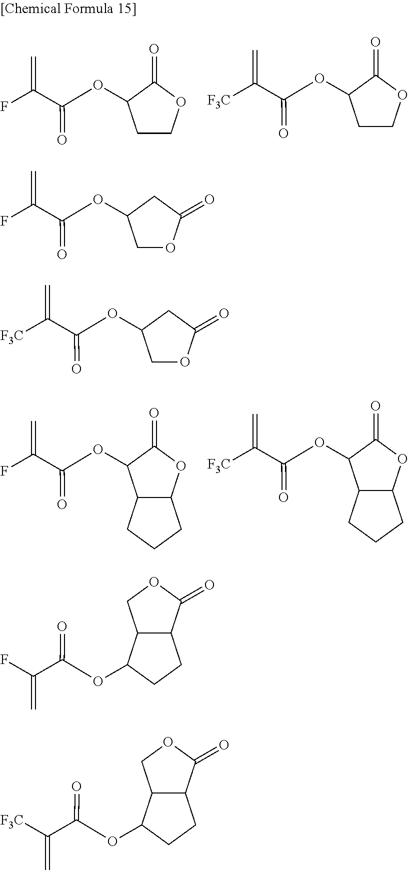

The monomers represented by Formula (X) can be synthesized by a known method. The production method is not particularly limited, and examples thereof include an esterification reaction between a lactone ring in a monomer represented by Formula (X), an alcohol containing an -A¹-OH group that is to be bonded to the lactone ring, and an acrylic anhydride having a R^{X} group. The esterification reaction may be carried out preferably in the presence of a base such as diisopropylethylamine, triethylamine, dimethylethylamine, dimethylisopropylamine, diethylmethylamine, or diisopropylmethylamine.

### Resin

The resin of an embodiment of the present invention includes a polymerization unit represented by Formula (Y), and thereby exhibits good swelling resistance. Accordingly, the resin is preferably used as a photoresist resin.

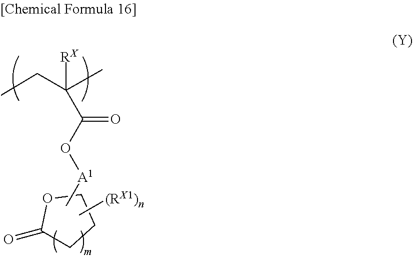

In Formula (Y), R^{X}, R^{X1}, A¹, n, and m are the same as those described with regard to Formula (X), and R^{X} denotes a halogen atom or an alkyl group having from 1 to 6 carbon atoms substituted with a halogen atom.

A¹ denotes a single bond or a linking group, and when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

The resin of an embodiment of the present invention is not particularly limited provided that it contains a polymerization unit represented by Formula (Y) above, and for example, may also contain at least one type of polymerization unit selected from the group consisting of polymerization units represented by Formula (Y1) and polymerization units represented by Formula (Y2).

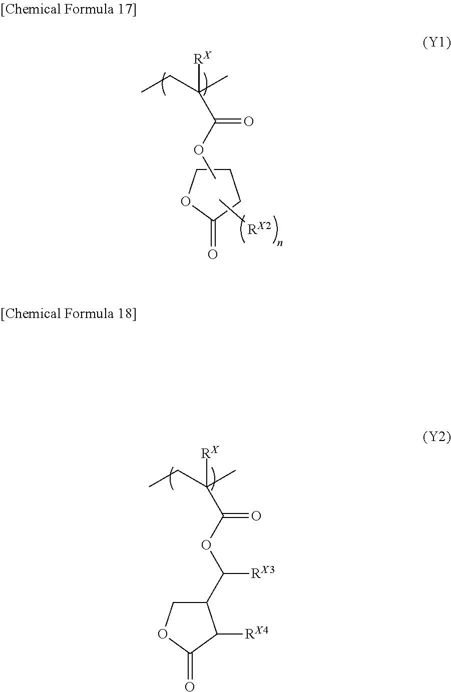

In Formulas (Y1) and (Y2), n, R^{X}, R^{X2}, R^{X3}, and R^{X4} are the same as those described with regard to Formulas (X1) and (X2).

Examples of the polymerization units represented by Formula (Y1) include polymerization units represented by Formulas (Y3) and (Y4).

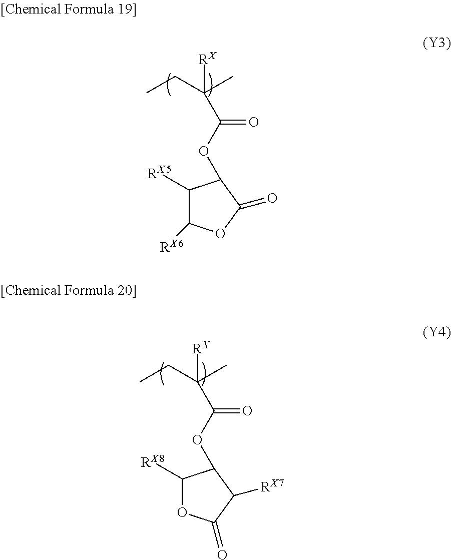

In Formulas (Y3) and (Y4), R^{X}, R^{X5}, R^{X6}, R^{X7}, and R^{X8} are the same as those described with regard to Formulas (X3) and (X4).

The resin of an embodiment of the present invention may have a group (sometimes referred to as an “acid degradable group”) which undergoes elimination of a portion thereof by the action of an acid to form a polar group. As a result, the resin of an embodiment of the present invention increases its polarity due to the action of the acid, and the solubility in an alkaline developing solution increases.

Examples of the polar group include phenolic a hydroxyl group, a carboxy group, a fluorinated alcohol group (preferably a hexafluoroisopropanol group), a sulfonic acid group, a sulfonamide group, a sulfonylimide group, a (alkylsulfonyl) (alkylcarbonyl) methylene group, an (alkylsulfonyl) (alkylcarbonyl) imide group; a bis(alkylcarbonyl) methylene group, a bis(alkylcarbonyl) imide group, a bis(alkylsulfonyl) methylene group, a bis(alkylsulfonyl) imide group, a tris(alkylcarbonyl) methylene group, a tris(alkylsulfonyl) methylene group, and other such acidic groups, and alcoholic hydroxyl groups. Among these, a carboxy group, fluorinated alcohol group (preferably hexafluoroisopropanol group) and sulfonic acid group are preferable.

The acid degradable group is preferably a group in which the hydrogen atom of the polar group above is substituted with a group that may be eliminated by an acid. Examples of the acid degradable group include —C(R^{I}) (R^{II}) (R^{III}), and —C(R^{Iv})(R^{V})(OR^{VI}). In the formulas, R^{I} to R^{III} and R^{VI} each independently represent an alkyl group, a cycloalkyl group, an aryl group, an aralkyl group, or an alkenyl group. R^{IV} and R^{V} each independently represent a hydrogen atom, an alkyl group, a cycloalkyl group, an aryl group, an aralkyl group, or an alkenyl group. At least two groups of R^{I} to R^{III} may be bonded to each other to form a ring. Additionally, the R^{IV} and R^{V} may be bonded to each other to form a ring.

The number of carbon atoms in the acid degradable group is not particularly limited, but is preferably 4 or greater, and more preferably 5 or greater. The upper limit of the number of carbon atoms is not particularly limited, but is preferably 20.

The alkyl group of the R^{I} to R^{VI} is preferably an alkyl group having from 1 to 8 carbon atoms, and examples thereof include a methyl group, an ethyl group, a propyl group, a n-butyl group, a s-butyl group, a t-butyl group, a hexyl group, and an octyl group.

The cycloalkyl group of the R^{I} to R^{VI} may be a monocyclic hydrocarbon group or a polycyclic (bridged cyclic) hydrocarbon group. The monocyclic hydrocarbon group is preferably a cycloalkyl group having from 3 to 8 carbon atoms, and examples thereof include a cyclopropyl group, a cyclobutyl group, a cyclopentyl group, a cyclohexyl group, and a cyclooctyl group. The polycyclic hydrocarbon group is preferably a cycloalkyl group having from 6 to 20 carbon atoms, and examples thereof include an adamantyl group, a norbornyl group, an isoboronyl group, a camphanyl group, a dicyclopentyl group, an α-pinel group, a tricyclodecanyl group, a tetracyclododecyl group, and an androstanyl group. Note that at least one carbon atom in the cycloalkyl group may be substituted with a hetero atom such as an oxygen atom.

The aryl group of the R^{I} to R^{VI} is preferably an aryl group having from 6 to 14 carbon atoms, and examples thereof include a phenyl group, a naphthyl group, and an anthryl group.

The aralkyl group of the R^{I} to R^{VI} is preferably an aralkyl group having from 7 to 12 carbon atoms, and examples thereof include a benzyl group, a phenethyl group, and a naphthylmethyl group.

The alkenyl group of the R^{I} to R^{VI} is preferably an alkenyl group having from 2 to 8 carbon atoms, and examples thereof include a vinyl group, an allyl group, a butenyl group, and a cyclohexenyl group.

A cycloalkane ring is preferable as the ring formed by mutually bonding at least two groups of R^{I} to R^{III}, and as the ring formed by bonding R^{IV} and R^{V}. As the cycloalkane ring, monocyclic cycloalkane rings such as a cyclopropane ring, a cyclobutane ring, a cyclopentane ring, and a cyclohexane ring; and polycyclic cycloalkane rings such as a norbornane ring, a tricyclodecane ring, a tetracyclododecane ring, and an adamantane ring are preferable.

Note that the alkyl group, cycloalkyl group, aryl group, aralkyl group, alkenyl group, and cycloalkane ring in R^{I} to R^{VI} may each have a substituent.

As the acid degradable group, among these, a t-butyl group, t-amyl group, and groups represented by Formulas (I) to (IV) are preferable.

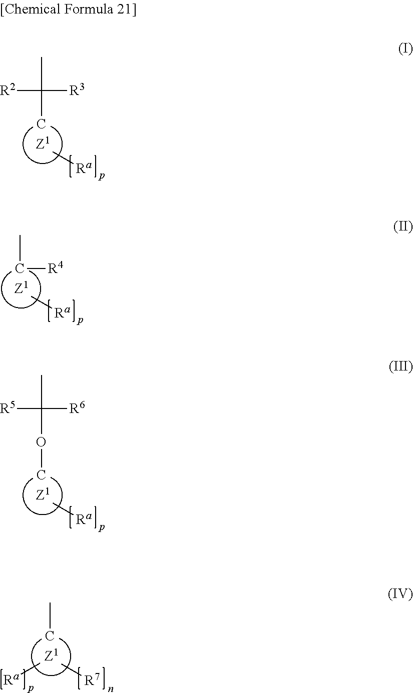

The R² to R⁷, R^{a}, n, p, and ring Z¹ in Formulas (I) to (IV) are the same as the respective R² to R⁷, R^{a}, n, p, and ring Z¹ in Formulas (a1) to (a4) described below.

The acid degradable group may be provided via a spacer. The spacer is the same as the linking group illustrated and described as A in Formula (1) described below.

The resin of an embodiment of the present invention preferably includes an acid degradable group, as a polymerization unit having an acid degradable group. Examples of the polymerization unit having such an acid degradable group include polymerization units represented by Formula (1) below.

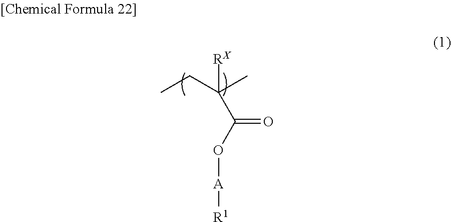

In Formula (1), R¹ denotes the acid degradable group. In addition, in Formula (1), R denotes a hydrogen atom, a halogen atom, or an alkyl group which has from 1 to 6 carbon atoms and may have a halogen atom. Examples of the halogen atom include a chlorine atom, a bromine atom, and an iodine atom. Examples of the alkyl group having from 1 to 6 carbon atoms include a methyl group, an ethyl group, a propyl group, an isopropyl group, a n-butyl group, an isobutyl group, a s-butyl group, a t-butyl group, a pentyl group, an isoamyl group, a s-amyl group, a t-amyl group, and a hexyl group. Examples of the alkyl group having from 1 to 6 carbon atoms and having a halogen atom include groups (halo (C₁₋₆) alkyl groups) in which one or more of the hydrogen atoms constituting the alkyl group are substituted with halogen atoms, such as a trifluoromethyl group, and a 2,2,2-trifluoroethyl group.

In Formula (1), A denotes a single bond or a linking group. Examples of the linking group include a carbonyl group (—C(═O)—), an ether bond (—O—), an ester bond (—C(═O)—O—), an amide bond (—C(═O)—NH—), a carbonate bond (—O—C(═O)—O—), a group in which a plurality of these are linked, and a group in which an alkylene group and these groups are bonded. Examples of the alkylene group include a straight or branched chain alkylene group such as a methylene group, a methylmethylene group, a dimethylmethylene group, an ethylene group, a propylene group, and a trimethylene group; and divalent alicyclic hydrocarbon groups (particularly divalent cycloalkylene groups) such as a 1,2-cyclopentylene group, a 1,3-cyclopentylene group, a cyclopentylidene group, a 1,2-cyclohexylene group, a 1,3-cyclohexylene group, a 1,4-cyclohexylene group, and a cyclohexylidene group.

Among the polymerization units represented by Formula (1) above, the resin of an embodiment of the present invention preferably includes at least one type of polymerization unit selected from the group consisting of polymerization units represented by Formulas (a1) to (a4). Note that the “at least one type of polymerization unit selected from the group consisting of polymerization units represented by Formulas (a1) to (a4)” may be referred to as a “monomer unit a”.

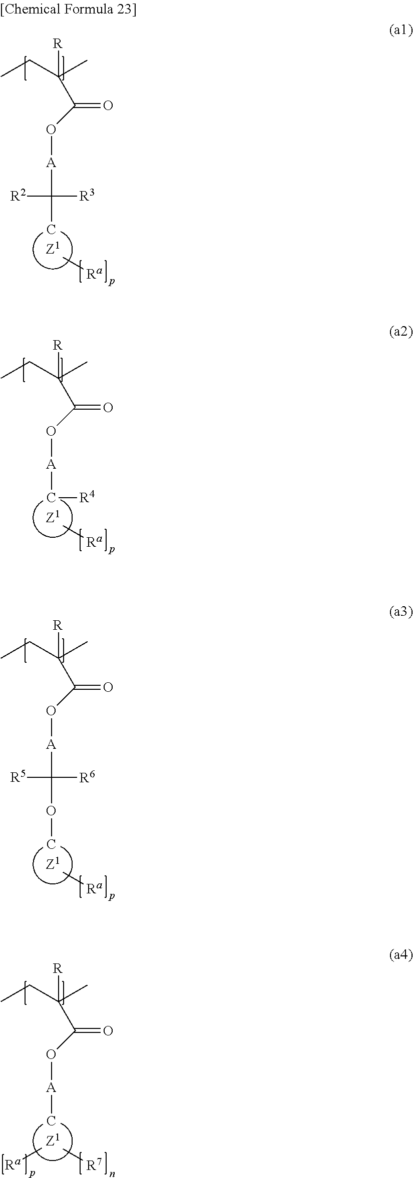

In the polymerization units represented by Formulas (a1) to (a4) above, similar to the R in Formula (1), R denotes a hydrogen atom, a halogen atom, or an alkyl group which has from 1 to 6 carbon atoms and may have a halogen atom, and A denotes a single bond or a linking group. Among these, A in Formulas (a1) to (a4) is preferably a single bond or a group in which an alkylene group and a carbonyloxy group are bonded (alkylene-carbonyloxy group). R² to R⁴ may be the same or different and denote an alkyl group which has from 1 to 6 carbon atoms and may have a substituent. Note that R² and R³ may be bonded to each other to form a ring. R⁵ and R⁶ may be the same or different and denote a hydrogen atom or an alkyl group which has from 1 to 6 carbon atoms and may have a hydrogen atom or a substituent. R⁷ denotes a —COOR^{c} group, and R^{c} denotes a tertiary hydrocarbon group, a tetrahydrofuranyl group, a tetrahydropyranyl group, or an oxepanyl group, each of which may have a substituent. n denotes an integer from 1 to 3. When n is 2 or 3, the multiple R⁷ may each be the same or different. R^{a} is a substituent bonded to a ring Z¹, and may be the same or different, and denotes an oxo group, an alkyl group, a hydroxy group that may be protected by a protecting group, a hydroxyalkyl group that may be protected by a protecting group, or a carboxy group that may be protected by a protecting group. p denotes an integer from 0 to 3. The ring Z¹ denotes an alicyclic hydrocarbon ring having from 3 to 20 carbon atoms. When p is 2 or 3, the multiple R^{a} may each be the same or different.

Examples of the alkyl group in the R^{a} include alkyl groups having from 1 to 6 carbon atoms such as a methyl group, an ethyl group, a propyl group, an isopropyl group, a n-butyl group, a s-butyl group, a t-butyl group, a pentyl group, an isoamyl group, a s-amyl group, a t-amyl group, and a n-hexyl group.

Examples of the hydroxyalkyl group in the R^{a} include hydroxy C₁₋₆ alkyl groups such as a hydroxymethyl group, a 2-hydroxyethyl group, a 1-hydroxyethyl group, a 3-hydroxypropyl group, a 2-hydroxypropyl group, a 4-hydroxybutyl group, and a 6-hydroxyhexyl group.

Examples of protecting groups that may be provided to the hydroxy group and hydroxyalkyl group in the R^{a} include C₁₋₄ alkyl groups such as a methyl group, an ethyl group, and a t-butyl group; groups that form an acetal bond together with an oxygen atom constituting a hydroxy group (for example, C₁₋₄ alkyl-O—C₁₋₄ alkyl groups such as a methoxymethyl group); and groups that form an ester bond together with an oxygen atom constituting a hydroxy group (for example, an acetyl group, and a benzoyl group).

Examples of the protecting group to the carboxy group in the R^{a} include C₁₋₆ alkyl groups such as a methyl group, an ethyl group, a propyl group, an isopropyl group, a n-butyl group, a s-butyl group, a t-butyl group, a pentyl group, an isoamyl group, a s-amyl group, a t-amyl group, and a hexyl group; and a 2-tetrahydrofuranyl group, a 2-tetrahydropyranyl group, and a 2-oxepanyl group.

Examples of the alkyl group having from 1 to 6 carbon atoms in the R² to R⁶ include straight or branched chain alkyl groups such as a methyl group, an ethyl group, a propyl group, an isopropyl group, a n-butyl group, an isobutyl group, a s-butyl group, a t-butyl group, a pentyl group, an isoamyl group, a s-amyl group, a t-amyl group, and a hexyl group. Among these, C₁₋₄ alkyl groups are preferable, C₁₋₃ alkyl groups are more preferable, and C₁₋₂ alkyl groups are even more preferable.

Examples of the substituent that may be provided to the alkyl group having from 1 to 6 carbon atoms in the R² to R⁶ include a halogen atom, a hydroxy group, a substituted hydroxy group (for example, C1-4 alkoxy groups such as methoxy, ethoxy, and propoxy groups), and a cyano group. Examples of the alkyl group having from 1 to 6 carbon atoms and having a substituent include halo (C₁₋₆) alkyl groups in which one or more of the hydrogen atoms constituting the alkyl group are substituted with halogen atoms such as a trifluoromethyl group, and a 2,2,2-trifluoroethyl group; and a hydroxymethyl group, a 2-hydroxyethyl group, a methoxymethyl group, a 2-methoxyethyl group, an ethoxymethyl group, a 2-ethoxyethyl group, a cyanomethyl group, and a 2-cyanoethyl group.

When R² and R³ are bonded to each other to form a ring, the ring may be, for example, an alicyclic hydrocarbon ring which has from 3 to 12 carbon atoms, and may have a substituent.

Examples of the tertiary hydrocarbon group in R^{c} include t-butyl groups and t-amyl groups.

Examples of the substituent that may be included in the tertiary hydrocarbon group in the R^{c} include a halogen atom, a hydroxy group, a substituted hydroxy group (for example, C₁₋₄ alkoxy groups such as a methoxy group, an ethoxy group, and a propoxy group), and a cyano group.

Examples of the alicyclic hydrocarbon ring having from 3 to 20 carbon atoms in the ring Z¹ include cycloalkane rings of approximately 3 to 20 members (preferably 3 to 15 members, particularly preferably 5 to 12 members) such as a cyclopropane ring, a cyclobutane ring, a cyclopentane ring, a cyclohexane ring, and a cyclooctane ring; monocyclic alicyclic hydrocarbon rings such as cycloalkene rings of approximately 3 to 20 members (preferably 3 to 15 members, particularly preferably 5 to 10 members) such as a cyclopropene ring, a cyclobutene ring, a cyclopentene ring, and a cyclohexene ring; an adamantane ring; rings containing a norbornane ring or norbornene ring such as a norbornane ring, a norbornene ring, a bornane ring, an isobornane ring, a tricyclo[5.2.1.0^{2,6}] decane ring, and a tetracyclo [4.4.0.1^{2,5}.1^{7,10}] dodecane ring; rings with a hydrogenated polycyclic aromatic condensed ring (preferably a fully hydrogenated ring) such as a perhydroindene ring, a decalin ring (perhydronaphthalene ring), a perhydrofluorene ring (tricyclo [7.4.0.0^{3,8}] tridecane ring), and a perhydroanthracene ring; and bridged cyclic hydrocarbons of approximately 2 to 6 rings including bridged hydrocarbon rings of a two ring system, a three ring system, or a four ring system (e.g., bridged hydrocarbon rings of approximately 6 to 20 carbon atoms) such as a tricyclo [4.2.2.1^{2,5}] undecane ring.

Specific examples of the monomer unit a include monomer units represented by the following formulas. In the monomer units represented by the formulas below, R^{d} denotes a methyl group or a hydrogen atom, and Re denotes a methyl group or a hydrogen atom. Additionally, the bonding position of Re to the alicyclic hydrocarbon ring is not particularly limited, and one or a plurality of Re may be bonded to any carbon atom of the carbon atoms constituting the alicyclic hydrocarbon ring. When a monomer unit represented by the following formulas includes two or more R^{e}, the two or more R^{e} may each be the same or different. The monomer unit a can be introduced into the resin by polymerizing the corresponding unsaturated carboxylate.

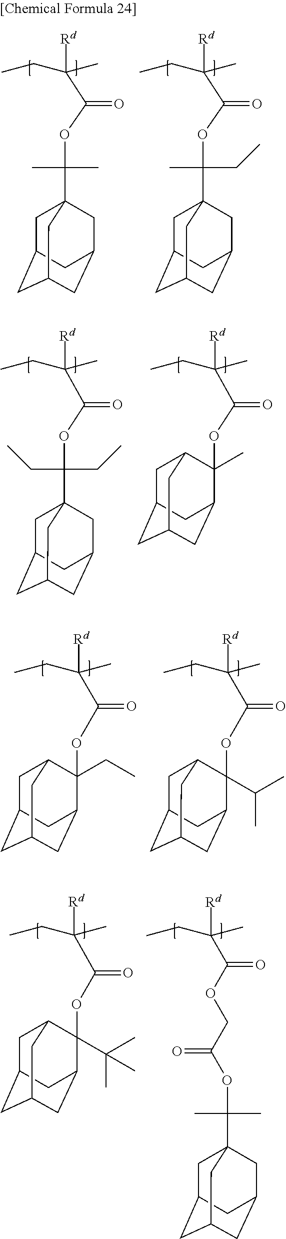

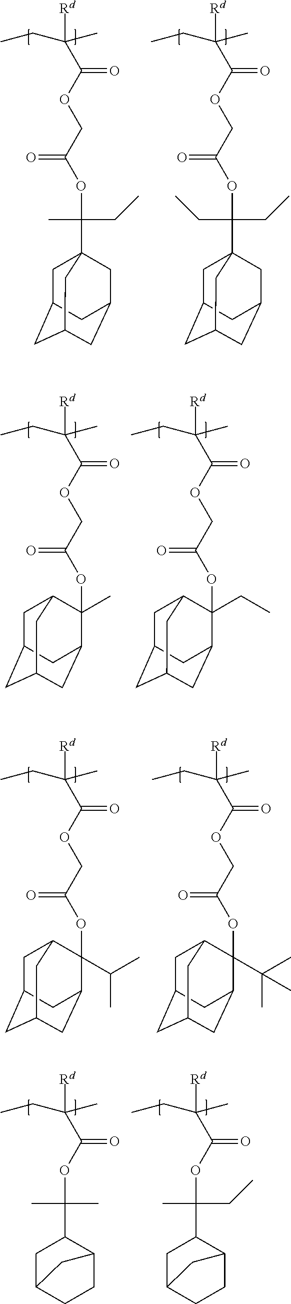

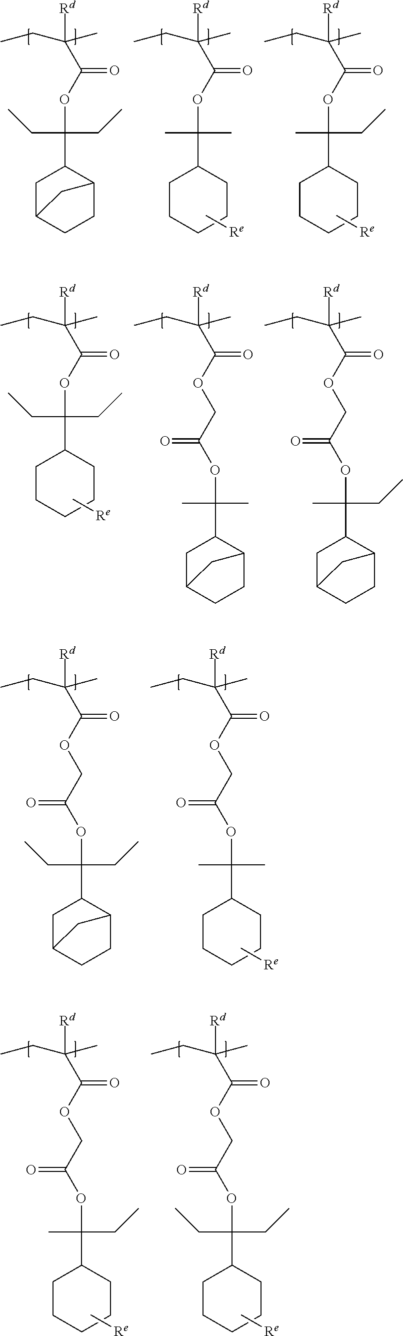

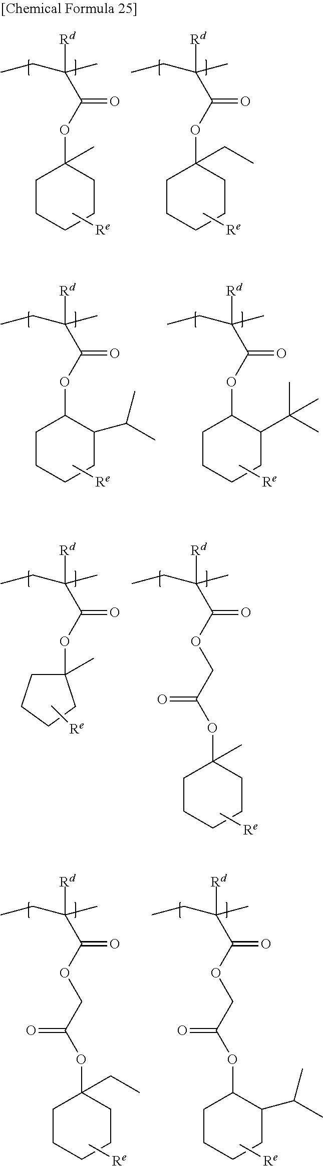

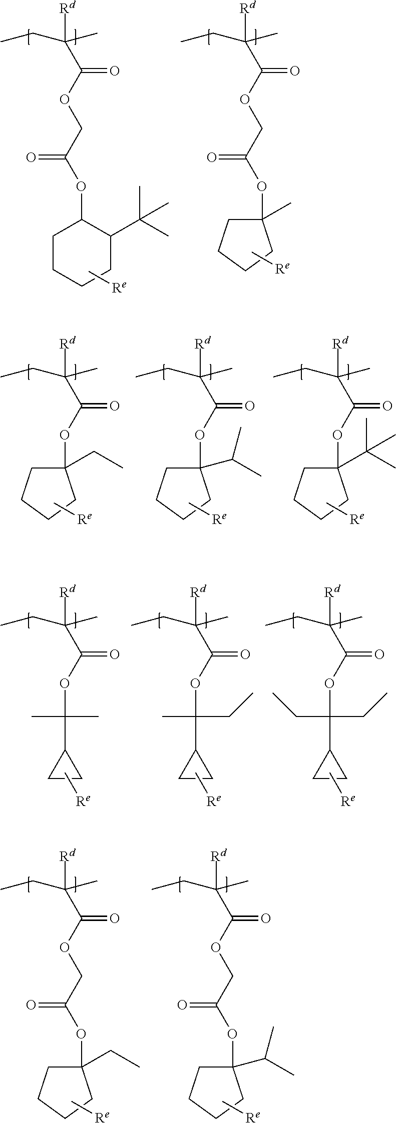

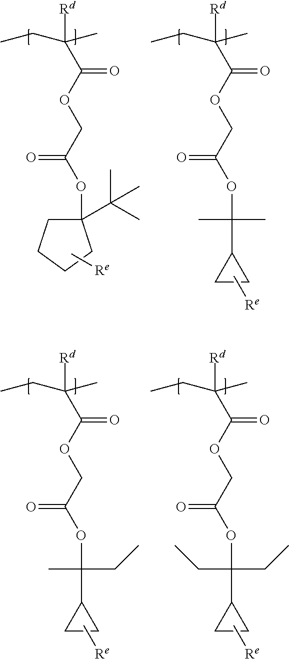

As the polymerization unit represented by Formula (1) above, in addition to the polymerization unit represented by the monomer unit a, polymerization units (excluding, however, polymerization units corresponding to a monomer unit b described below) that correspond to an unsaturated carboxylate containing a lactone ring, in which an oxygen atom constituting an ester bond is bonded to the β-position of the lactone ring, and at least one hydrogen atom is provided at the α-position of the lactone ring can also be used.

One type of the polymerization unit represented by Formula (1) may be used alone, or a combination of two or more types may be used. The polymerization units represented by Formula (1) above preferably include at least one type of polymerization unit selected from the group consisting of polymerization units represented by Formulas (a1) to (a4). In addition, as the polymerization units represented by Formula (1) above, a combination of at least one type of polymerization unit selected from the group consisting of polymerization units represented by Formulas (a1) to (a4), and a polymerization unit represented by Formula (1) (other polymerization unit represented by Formula (1)) other than the at least one type of polymerization unit selected from the group consisting of polymerization units represented by Formulas (a1) to (a4) above may be used The other polymerization unit represented by Formula (1) is preferably a polymerization unit represented by Formula (1) in which R¹ is a group having a tertiary hydrocarbon group (for example, a t-butyl group, and a t-amyl group).

Furthermore, the resin of an embodiment of the present invention preferably includes an alicyclic skeleton having at least [—C(═O)—O—], [—S(═O)₂—O—], or [—C(═O)—O—C(═O)—]. Including the alicyclic skeleton can impart a strong adhesion to the substrate and etching resistance to the resin. The resin of an embodiment of the present invention preferably includes the alicyclic skeleton, as a polymerization unit having the alicyclic skeleton. Note that a polymerization unit containing an alicyclic skeleton having at least [—C(═O)—O—], [—S(═O)₂—O—], or [—C(═O)—O—C(═O)—] described above may be referred to as a “monomer unit b”. Also note that the monomer unit b does not include a unit corresponding to the polymerization unit represented by Formula (Y).

Of the monomer units b, the resin of an embodiment of the present invention preferably includes at least one type of polymerization unit selected from the group consisting of polymerization units represented by Formulas (b1) to (b5) below (except for those corresponding to the polymerization units represented by Formula (Y)). In Formulas (b1) to (b5) below, R denotes a hydrogen atom, a halogen atom, or an alkyl group which has from 1 to 6 carbon atoms and may have a halogen atom, and A denotes a single bond or a linking group. X denotes no bond, a methylene group, an ethylene group, an oxygen atom, or a sulfur atom. Y denotes a methylene group or a carbonyl group. Z denotes a divalent organic group (such as an alkylene group exemplified and described as an alkylene group that may be included in A in the polymerization units represented by Formulas (a1) to (a4) (particularly a straight-chain alkylene group having from 1 to 3 carbon atoms)). V¹ to V³ may be the same or different, and denote —CH₂—, [—C(═O)—], or [—C(═O)—O—]. At least one of V¹ to V³ is [—C(═O)—O—]. R⁸ to R¹⁴ may be the same or different, and denote a hydrogen atom, a fluorine atom, an alkyl group that may have a fluorine atom, a hydroxy group that may be protected by a protecting group, a hydroxyalkyl group that may be protected by a protecting group, a carboxy group that may be protected by a protecting group, or a cyano group.

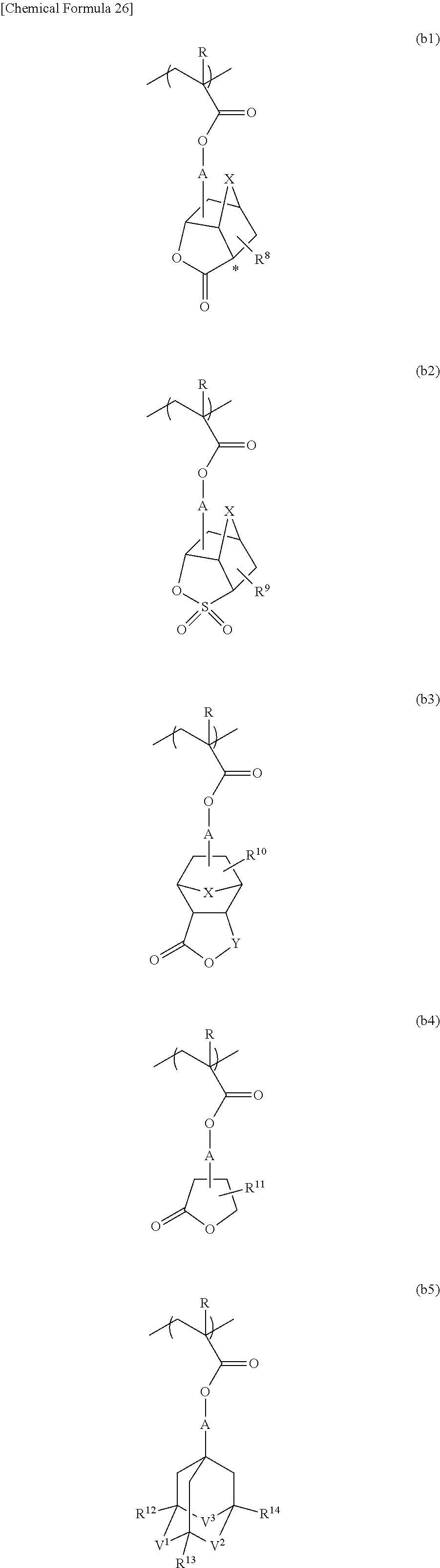

Examples of R and A in the polymerization units represented by Formulas (b1) to (b5) include the same examples as those given for the R and A in the polymerization units represented by Formulas (a1) to (a4). With respect to the R⁸ to R¹⁴ in the polymerization units represented by Formulas (b1) to (b5), examples of the alkyl group, hydroxy group that may be protected by a protecting group, hydroxyalkyl group that may be protected by a protecting group, and carboxy group that may be protected by a protecting group include the same examples as those given with respect to R^{a} in the polymerization units represented by Formulas (a1) to (a4).

Examples of the alkyl group having a fluorine atom in R⁸ to R¹⁴ include groups (fluoro (C₁₋₆) alkyl groups) in which one or more of the hydrogen atoms constituting the alkyl group are substituted with fluorine atoms, such as a trifluoromethyl group, and a 2,2,2-trifluoroethyl group.

In the polymerization units represented by the above Formulas (b1) to (b4), the number of moieties of each of the R⁸ to R¹¹ is preferably one or more, and preferably from 1 to 3. In addition, when the polymerization units represented by Formulas (b1) to (b4) includes two or more of the R⁸ to R¹¹, each of the two or more R⁸ to R¹¹ may be the same or different.

Among the monomer units b, a polymerization unit represented by Formula (b1) with R⁸ being an electron-withdrawing group such as a cyano group, a group having an amide group, a group having an imide group, or a fluoro (C₁₋₆) alkyl group; a polymerization unit represented by Formula (b2); a polymerization unit represented by Formula (b3) with Y being a carbonyl group; a polymerization unit represented by Formula (b4); and a polymerization unit represented by Formula (b5) are preferable from the viewpoints of being able to impart excellent substrate adhesion and etching resistance to the resin, to provide excellent solubility in an alkaline developing solution, and to form fine patterns with high precision.

In Formula (b1), when R⁸ is an electron-withdrawing group such as a cyano group, a group having an amide group, a group having an imide group, or a fluoro (C₁₋₆) alkyl group, R⁸ is particularly preferably bonded at least to the carbon atom designated by * in Formula (b1).

Specific examples of the monomer unit b include polymerization units represented by the following formulas. In the monomer units represented by the formulas below, R^{d} denotes a methyl group or a hydrogen atom. The monomer unit b can be introduced into the resin by polymerizing the corresponding unsaturated carboxylate.

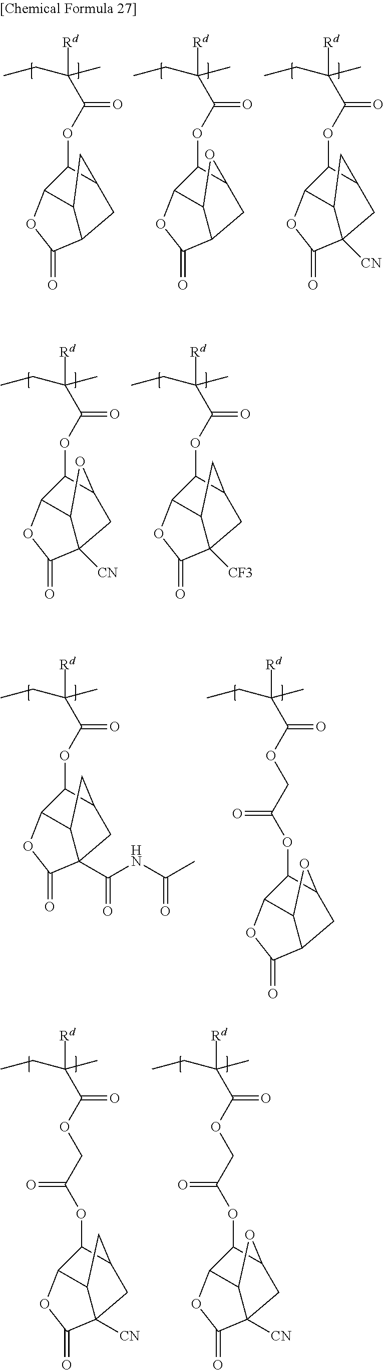

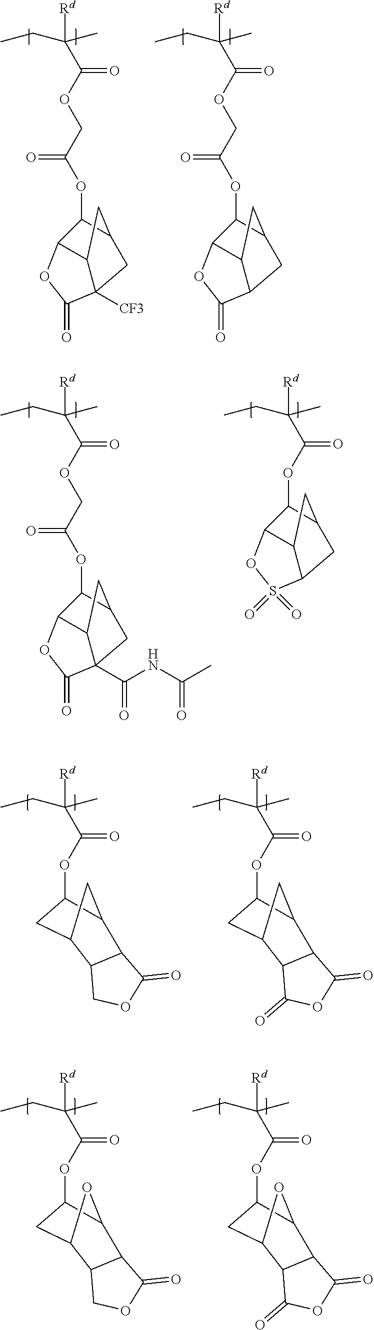

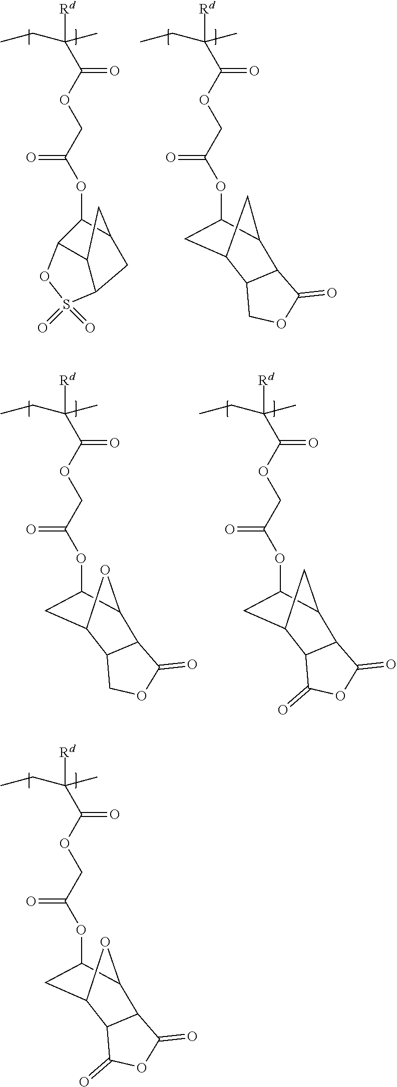

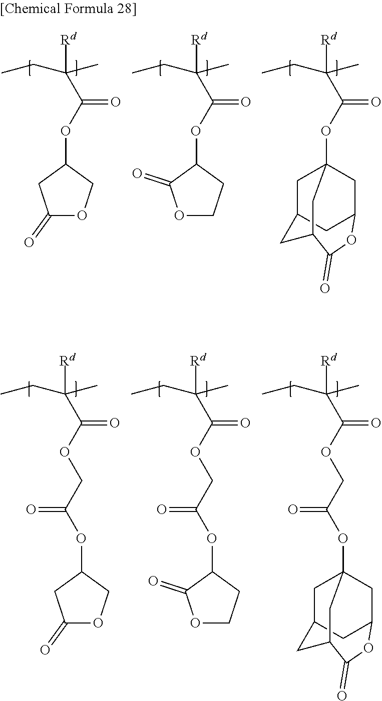

The resin of an embodiment of the present invention may further have a monomer unit c. The monomer unit c is a polymerization unit represented by Formula (c1) below. When the resin of an embodiment of the present invention contains the monomer unit c as a polymerization unit, high transparency and etching resistance can be imparted to the photoresist resin. In Formula (c1), R denotes a hydrogen atom, a halogen atom, or an alkyl group which has from 1 to 6 carbon atoms and may have a halogen atom. A denotes a single bond or a linking group. R^{b} denotes a hydroxy group that may be protected by a protecting group, a hydroxyalkyl group that may be protected by a protecting group, a carboxy group that may be protected by a protecting group, or a cyano group, and among these, a hydroxy group and a cyano group are preferable. q denotes an integer from 1 to 5. The ring Z² denotes an alicyclic hydrocarbon ring having from 6 to 20 carbon atoms. When q denotes an integer from 2 to 5, from 2 to 5 R^{b} may each be the same or different.

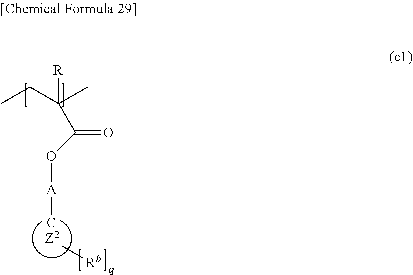

Examples of R and A in the polymerization units represented by Formula (c1) include the same examples as those given for the R and A in the polymerization units represented by Formulas (a1) to (a4). With respect to the R^{b} in the polymerization units represented by Formula (c1), examples of the hydroxy group that may be protected by a protecting group, the hydroxyalkyl group that may be protected by a protecting group, and the carboxy group that may be protected by a protecting group include the same examples as those given for R^{a} in the polymerization units represented by Formulas (a1) to (a4).

The ring Z² in the polymerization unit represented by Formula (c1) denotes an alicyclic hydrocarbon ring having from 6 to 20 carbon atoms, and examples include cycloalkane rings of approximately 6 to 20 members (preferably from 6 to 15 members, and particularly preferably from 6 to 12 members) such as a cyclohexane ring and a cyclooctane ring; monocyclic alicyclic hydrocarbon rings such as cycloalkene rings of approximately 6 to 20 members (preferably from 6 to 15 members, and particularly preferably from 6 to 10 members) such as a cyclohexene ring; an adamantane ring; rings containing a norbornane ring or norbornene ring such as a norbornane ring, a norbornene ring, a bornane ring, an isobornane ring, a tricyclo[5.2.1.0^{2,6}] decane ring, and a tetracyclo[4.4.0.1^{2,5}.1^{7,10}] dodecane ring; rings with a hydrogenated polycyclic aromatic condensed ring (preferably a fully hydrogenated ring) such as a perhydroindene ring, a decalin ring (perhydronaphthalene ring), a perhydrofluorene ring (tricyclo [7.4.0.0^{3,8}] tridecane ring), and a perhydroanthracene ring; and bridged cyclic hydrocarbons of approximately 2 to 6 rings including bridged hydrocarbon rings of a two ring system, a three ring system, or a four ring system, etc. (e.g., bridged hydrocarbon rings of approximately 6 to 20 carbon atoms) such as a tricyclo [4.2.2.1^{2,5}] undecane ring or other such. Among these, a ring containing a norbornane ring or a norbornene ring; and an adamantane ring are preferable as the ring Z².

Specific examples of the monomer unit c include polymerization units represented by the following formulas. In the polymerization unit represented by the following formulas, R^{d} denotes a methyl group or a hydrogen atom. The monomer unit c can be introduced into the resin by polymerizing the corresponding unsaturated carboxylate.

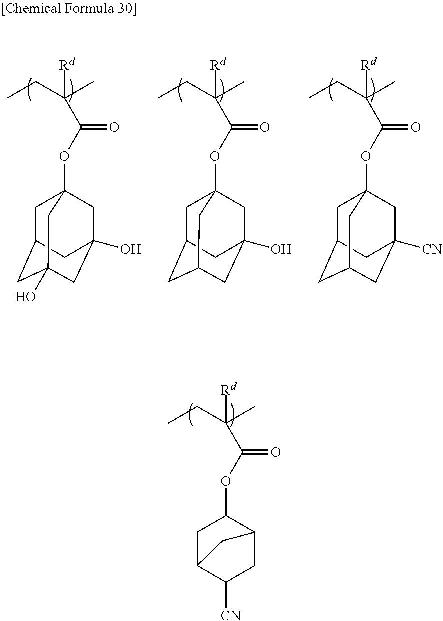

The resin of an embodiment of the present invention includes a polymerization unit represented by Formula (Y), and more preferably includes at least one monomer unit selected from the group consisting of the monomer unit a, the monomer unit b, and the monomer unit c. In this case, the content of the polymerization units represented by Formula (Y) in the resin of an embodiment of the present invention is, for example, from 5 to 95 mol %, preferably from 10 to 90 mol %, more preferably from 20 to 80 mol %, and even more preferably from 30 to 60 mol %, based on the total amount of the monomer units (polymerization units) constituting the resin. Moreover, the content of the monomer unit a is, for example, from 10 to 90 mol %, preferably from 20 to 80 mol %, more preferably from 30 to 70 mol %, and even more preferably from 40 to 60 mol %, based on the total amount of the monomer units constituting the resin. Furthermore, the content of the monomer unit b when the resin of an embodiment of the present invention contains the monomer unit b is, for example, from 0 to 80 mol %, preferably from 10 to 60 mol %, and more preferably from 20 to 50 mol %, based on the total amount of the monomer units constituting the resin. Furthermore, the content of the monomer unit c when the resin of an embodiment of the present invention contains the monomer unit c is, for example, from 0 to 40 mol %, preferably from 1 to 30 mol %, and more preferably from 3 to 25 mol %, based on the total amount of the monomer units constituting the resin.

In addition, the weight average molecular weight (Mw) of the resin of an embodiment of the present invention is from 1000 to 50000, preferably from 2000 to 30000, more preferably from 3000 to 20000, and particularly preferably from 4000 to 15000. The molecular weight distribution (ratio of the weight average molecular weight to the number average molecular weight: Mw/Mn) of the resin of an embodiment of the present invention is not particularly limited as long as it is not greater than 2.5, and, for example, is from 1.0 to 2.2, and preferably from 1.0 to 2.0. Note that in the present specification, the weight average molecular weight (Mw) and the number average molecular weight (Mn) can be measured, for example, through GPC using polystyrene as a standard material, and is preferably measured by the method used in the examples.

The acid value of the resin of an embodiment of the present invention is, for example, not greater than 0.10 mmol/g, preferably not greater than 0.05 mmol/g, and more preferably not greater than 0.03 mmol/g. When the acid value is not greater than 0.10 mmol/g, the acid degradable groups in the resin are protected without elimination, and therefore the resin of an embodiment of the present invention exhibits excellent resist performance, and favorable stability over time. Note that the lower limit of the acid value is, for example, 0 mmol/g.

### Resin Production Method

The method of producing the resin of an embodiment of the present invention is not particularly limited, and examples thereof include dropwise polymerization method. Examples of the dropwise polymerization method include a method including adding the monomer or a solution containing the monomer dropwise in the presence of a polymerization initiator to polymerize the monomer. More specific examples include (1) adding dropwise a solution containing a polymerization initiator and a monomer, and (2) adding dropwise a monomer or a solution containing a monomer into a solution containing a polymerization initiator. The dropwise polymerization method may be performed in the presence of a chain transfer agent in addition to a polymerization initiator. Examples of monomers include monomers of an embodiment of the present invention and monomers corresponding to the monomer unit a, the monomer unit b, and the monomer unit c.

A known radical polymerization initiator can be used as the polymerization initiator, and examples thereof include azo-based compounds, peroxide-based compounds, and redox-based compounds, and in particular, preferred examples include dimethyl-2,2′-azobisisobutyrate, azobisisobutyronitrile, 2,2′-azobis(2-methylbutyronitrile), t-butyl peroxypivalate, di-t-butyl peroxide, isobutyryl peroxide, lauroyl peroxide, succinic peroxide, dicinnamyl peroxide, di-n-propyl peroxydicarbonate, t-butyl peroxyallyl monocarbonate, benzoyl peroxide, hydrogen peroxide, and ammonium persulfate.

The amount of the polymerization initiator to be used may be an amount necessary to obtain a resin having a desired molecular weight distribution, and, for example, is from 0.05 to 120 moles, preferably from 0.1 to 50 moles, and more preferably from 0.5 to 10 moles based on the total amount of the monomers (100 moles). In addition, the amount of the polymerization initiator to be used based on the total amount (100 parts by weight) of the monomers is, for example, from 0.01 to 30 parts by weight, preferably from 0.2 to 20 parts by weight, and more preferably from 0.5 to 10 parts by weight.

A known chain transfer agent used in radical polymerization can be used as the chain transfer agent, and examples include thiols such as n-dodecyl mercaptan, n-octyl mercaptan, n-butyl mercaptan, tert-butyl mercaptan, n-lauryl mercaptan, mercaptoethanol, mercaptopropanol, and triethylene glycol dimercaptan; thiol acids and esters thereof such as mercaptopropionic acid, thiobenzoic acid, thioglycolic acid, and thiomalic acid, and alkyl esters thereof; alcohols such as isopropyl alcohol, amines such as dibutylamine, hypophosphites such as sodium hypophosphite, α-methylstyrene dimer, terpinolene, myrcene, limonene, α-pinene, and β-pinene.

The amount of the chain transfer agent to be used is not particularly limited, but is preferably from 0.001 to 100 mol, more preferably from 0.01 to 50 mol, even more preferably from 0.1 to 30 mol, and particularly preferably from 1 to 10 mol, based on the total amount of the monomers (100 mol). In addition, the amount of the chain transfer agent to be used based on the total amount of the monomers (100 parts by weight) is not particularly limited, but is preferably from 0.1 to 100 parts by weight, more preferably from 0.5 to 50 parts by weight, and even more preferably from 1 to 25 parts by weight.

The polymerization step may be performed without a solvent or may be performed in the presence of a polymerization solvent. Examples of the polymerization solvent include glycol-based solvents (the glycol-based compounds), ester-based solvents, ketone-based solvents, ether-based solvents, amide-based solvents, sulfoxide-based solvents, monohydric alcohol-based solvents (the monohydric alcohol-based compounds), hydrocarbon-based solvents, and mixed solvents thereof. Examples of the glycol solvents include, besides the glycol-based compounds, propylene glycol monomethyl ether acetate, ethylene glycol monomethyl ether acetate, ethylene glycol monoethyl ether acetate, and ethylene glycol monobutyl ether acetate. Examples of the ester-based solvents include lactate-based solvents such as ethyl lactate; propionate-based solvents such as methyl 3-methoxy propionate; and acetate-based solvents such as methyl acetate, ethyl acetate, propyl acetate, and butyl acetate. Examples of the ketone-based solvents include acetone, methyl ethyl ketone, methyl isobutyl ketone, methyl amyl ketone, cyclopentanone, and cyclohexanone. Examples of the ether-based solvents include chain ethers such as diethyl ether, diisopropyl ether, dibutyl ether, and dimethoxy ethane; and cyclic ethers such as tetrahydrofuran, and dioxane. Examples of the amide-based solvents include N,N-dimethylformamide. Examples of the sulfoxide-based solvents include dimethyl sulfoxide. Examples of the hydrocarbon-based solvents include aliphatic hydrocarbons such as pentane, hexane, heptane, and octane; alicyclic hydrocarbons such as cyclohexane and methylcyclohexane; and aromatic hydrocarbons such as benzene, toluene, and xylene.

Preferred polymerization solvents include glycol-based solvents such as propylene glycol monomethyl ether and propylene glycol monomethyl ether acetate; ester-based solvents such as ethyl lactate; ketone-based solvents such as acetone, methyl ethyl ketone, methyl isobutyl ketone, methyl amyl ketone, cyclopentanone, and cyclohexanone; and mixed solvents thereof.

The dropwise addition of solution containing a monomer may be continuous dropwise addition (an aspect of adding dropwise over a certain period of time) or may be intermittent dropwise addition (an aspect in which dropwise addition is divided into multiple additions). Furthermore, the rate and the like of dropwise addition may be changed one or more times during dropwise addition.

The total dropwise addition time of the solution containing a monomer (the time from the start of dropwise addition to the completion of dropwise addition) varies depending on the polymerization temperature, the type of monomer and the like, but is generally from 1 to 10 hours, preferably from 2 to 9 hours, and even more preferably from 3 to 8 hours. The temperature of the solution containing a monomer to be added dropwise is preferably not greater than 40° C. When the temperature of the solution containing a monomer is not greater than 40° C., there is a tendency to inhibit the production of a polymer having an excessive molecular weight during the initial stage of the reaction. Also, when the solution containing a monomer is at an excessively low temperature, the solution may crystallize depending on the type of monomer.

The polymerization temperature is not particularly limited, but is, for example, from 30 to 150° C., preferably from 50 to 120° C., and more preferably from 60 to 100° C. Note that during polymerization, the polymerization temperature may be changed one or more times within the range of polymerization temperatures described above.

In the polymerization step, a time for aging may be provided after the completion of the dropwise addition. The aging time is not particularly limited, but is, for example, preferably from 0.5 to 10 hours, and more preferably from 1 to 5 hours.

The polymer produced in the polymerization step can be recovered by precipitation (including re-precipitation), for example. For example, the target polymer can be obtained by procedures such as: adding a polymerization solution (polymer dope) into a solvent (precipitation solvent) to precipitate the polymer, or dissolving the polymer once again in an appropriate solvent, and adding the solution thereof into a solvent (re-precipitation solvent) to cause re-precipitation, or alternatively, diluting the polymerization solution (polymer dope) by adding a solvent (a re-precipitation solvent or a polymerization solvent) thereto. The precipitation or re-precipitation solvent may be either an organic solvent or water, or may be a mixed solvent.

The precipitation or re-precipitation solvent is not particularly limited, and known or customarily used solvents can be used. The precipitation or re-precipitation solvent may be the same solvent as the polymerization solvent described above, or may be a different solvent. Examples of the precipitation or re-precipitation solvent include organic solvents exemplified as the polymerization solvent, namely, glycol-based solvents, ester-based solvents, ketone-based solvents, ether-based solvents, amide-based solvents, sulfoxide-based solvents, monohydric alcohol-based solvents, and hydrocarbon-based solvents; halogenated hydrocarbons including, halogenated aliphatic hydrocarbons such as methylene chloride, chloroform, and carbon tetrachloride; and halogenated aromatic hydrocarbons such as chlorobenzene, and dichlorobenzene; nitro compounds such as nitromethane and nitroethane; nitriles such as acetonitrile and benzonitrile; carbonates such as dimethyl carbonate, diethyl carbonate, ethylene carbonate, and propylene carbonate; carboxylic acids such as acetic acid; and mixed solvents containing these solvents.

Among these, the precipitation or re-precipitation solvent is preferably a solvent containing at least a hydrocarbon (particularly an aliphatic hydrocarbon such as hexane or heptane) or an alcohol (such as, in particular, methanol, ethanol, propanol, isopropyl alcohol, or butanol). In such a solvent containing at least a hydrocarbon, the ratio of a hydrocarbon (e.g. aliphatic hydrocarbons such as hexane and heptane) to other solvents (e.g. esters such as ethyl acetate) is, for example, the hydrocarbon/other solvents (volume ratio; 25° C.)=10/90 to 99/1, preferably the hydrocarbon/other solvents (volume ratio; 25° C.)=30/70 to 98/2, and more preferably the hydrocarbon/other solvents (volume ratio; 25° C.)=50/50 to 97/3.

The precipitation or re-precipitation solvent is also preferably a mixed solvent of an alcohol (particularly methanol) and water, or a mixed solvent of a glycol-based solvent (particularly polyethylene glycol) and water. In this case, the ratio (volume ratio; 25° C.) of the organic solvent (alcohol or glycol-based solvent) to water is, for example, the organic solvent/water (volume ratio; 25° C.)=10/90 to 99/1, preferably the organic solvent/water (volume ratio; 25° C.)=30/70 to 98/2, and more preferably the organic solvent/water (volume ratio; 25° C.)=50/50 to 97/3.

The polymer obtained by precipitation (including re-precipitation) is optionally subjected to rinsing or a treatment of stirring and washing while untangling and dispersing the polymer in a solvent (sometimes referred to as a “re-pulping treatment”). Rinsing may be performed after the re-pulping treatment. Re-pulping with a solvent or rinsing the polymer produced by polymerization can efficiently remove residual monomers, low molecular weight oligomers, and the like that are adhered to the polymer.

In the production method of an embodiment of the present invention, among the solvents, a solvent containing at least a hydrocarbon (p articularly an aliphatic hydrocarbon such as hexane or heptane), an alcohol (particularly methanol, ethanol, propanol, isopropyl alcohol, and butanol, etc.), or esters (particularly, ethyl acetate, etc.) are preferable as the re-pulping and rinsing treatment solvents.

After the precipitation (including re-precipitation), re-pulping treatment, or rinsing, the solvent may be removed by, for example, decantation, filtration, or the like as necessary, and a drying treatment may be performed.

### Resin Composition

The resin composition of an embodiment of the present invention contains at least the resin of an embodiment of the present invention and a radiation sensitive acid generating agent.

A customarily used or known compound that efficiently generates acid by exposure to radiation such as visible light, ultraviolet light, far ultraviolet light, electron beams, and X-rays can be used as the radiation sensitive acid generating agent, and is a compound formed from a base nucleus and an acid that is generated. Examples of the base nucleus include onium salt compounds such as iodonium salts, sulfonium salts (including tetrahydrothiophenium salts), phosphonium salts, diazonium salts, and pyridinium salts, sulfonimide compounds, sulfone compounds, sulfonate compounds, disulfonyldiazomethane compounds, disulfonylmethane compounds, oxime sulfonate compounds, and hydrazine sulfonate compounds. Furthermore, examples of the acid generated by exposure include alkyl or fluorinated alkyl sulfonic acids, alkyl or fluorinated alkyl carboxylic acids, and alkyl or fluorinated alkyl sulfonyl imide acids. A single type may be used alone, or two or more types may be used.

The amount of the radiation sensitive acid generating agent to be used can be selected, as appropriate, in accordance with, the strength of the acid generated by irradiation with radiation, the ratio of each repeating unit in the resin, and the like, and for example, the amount to be used can be selected from a range of 0.1 to 30 parts by weight, preferably from 1 to 25 parts by weight, and even more preferably from 2 to 20 parts by weight.

The resin composition can be prepared, for example, by mixing the resin and the radiation sensitive acid generating agent in a solvent for a resist. As the solvent for a resist, a glycol-based solvent, an ester-based solvent, a ketone-based solvent, a solvent mixture of these solvents, and the like, which are exemplified as the polymerization solvent, can be used.

The resin concentration of the resin composition is, for example, from 3 to 40 wt. %. The resin composition may contain alkali-soluble component such as an alkali soluble resin (for example, a novolac resin, a phenolic resin, an imide resin, and a carboxy group-containing resin), a coloring agent (for example, a dye), and the like.

### Pattern Forming Method

The resin composition of an embodiment of the present invention is applied to a base material or substrate, dried, and then the coating film (resist film) is exposed via a prescribed mask (or further subjected to post-exposure baking) to form a latent image pattern, and then subjected to alkali dissolving to thereby achieve excellent swelling resistance and form a fine pattern with high precision.

Examples of the base material or substrate include silicon wafers, metals, plastics, glass, and ceramics. The resin composition can be applied using a known application means such as a spin coater, dip coater, and roller coater. The thickness of the coating film is, for example, preferably from 0.05 to 20 μm, and more preferably from 0.1 to 2 μm.

Exposure can be performed using radiation such as visible light, ultraviolet light, far ultraviolet light, electron beams, and X-rays.

An acid is generated from the radiation sensitive acid generating agent by exposure, and the acid readily promotes elimination of a protecting group (acid degradable group), such as a carboxy group of a polymerization unit of the resin composition (repeating unit having an acid degradable group) that becomes alkaline soluble by the action of an acid, and thereby a carboxy group or the like that contributes to solubilization is produced. As a result, the predetermined pattern can be formed with high precision by developing using an alkaline developing solution.

### EXAMPLES

Hereinafter, the present invention is described in further detail with reference to examples; however, the examples are by no means intended to limit the scope of the present invention. Note that the weight average molecular weight (Mw) and the number average molecular weight (Mn) of the resin were determined by GPC measurements (gel permeation chromatography) using a tetrahydrofuran solvent. Polystyrene was used as the standard sample, and a refractometer (Refractive Index Detector; RI detector) was used as the detector. Additionally, for the GPC measurements, three columns available from Showa Denko K.K. (trade name “KF-806 L”) were connected in series and used, and measurements were carried out at a column temperature of 40° C., an RI temperature of 40° C., and a tetrahydrofuran flow rate of 0.8 mL/min. The molecular weight distribution (Mw/Mn) was calculated from the measurements.

### Example 1 (Preparation of Monomer A)

In accordance with the method described in J. Chem. Soc. Perkin Trans. 1 (1999), 23, p. 3469, 3-hydroxyhexahydro-2H-cyclopenta [b] furan-2-one was obtained.

14.8 g of the obtained 3-hydroxyhexahydro-2H-cyclopenta [b] furan-2-one was dissolved in 148 g of THF, and 1.27 g of DMAP (N,N-dimethyl-4-aminopyridine), 14.0 g of sodium 2-fluoroacrylate, and 7.0 mg of methoquinone were added thereto. The solution was heated to 40° C., after which 39.9 g of EDCI.HCl (1-ethyl-3-(3-dimethylaminopropyl) carbodiimide hydrochloride) was added in five portions and stirred at 40° C. for 30 minutes. Next, 79.8 g of 10% hydrochloric acid was added dropwise, after which 148 g of ethyl acetate and 148 g of water were added. The organic phase was washed three times with 148 g of water, and then dried and concentrated (40° C., 30 Torr), and a crude product was thereby obtained. The product was purified through silica gel column chromatography, and 10.9 g of a monomer A represented by the following formula was obtained. The yield was 49%. In addition, the ¹H-NMR spectrum data is also shown below.

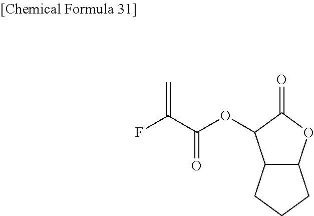

### Spectral Data

¹H-NMR (DMSO-d₆) δ5.88 (d, 1H), 5.84 (d, 1H), 5.75 (m, 1H), 5.05 (t, 1H), 3.15 (m, 1H), 1.88 (m, 2H), 1.62 (m, 4H)

Example 2 (Preparation of Monomer B) 10.0 g of a monomer B represented by the following formula was obtained in the same manner as in Example 1 with the exception that the 3-hydroxyhexahydro-2H-cyclopenta [b] furan-2-one was changed to α-hydroxy-γ-butyrolactone (Tokyo Chemical Industry Co., Ltd.). The yield was 55%. In addition, the ¹H-NMR spectrum data is also shown below.

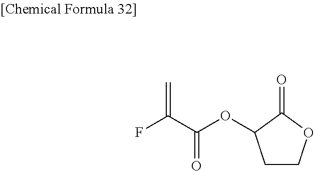

### Spectral Data

¹H-NMR (DMSO-d₆) δ5.88 (d, 1H), 5.84 (d, 1H), 5.47 (m, 1H), 4.30 (m, 2H), 2.34 (m, 2H)

### Example 3 (Preparation of Monomer C)

11.0 g of a monomer C represented by the following formula was obtained in the same manner as in Example 1 with the exception that the sodium 2-fluoroacrylate was changed to 2-(trifluoromethyl)acrylate (Tokyo Chemical Industry Co., Ltd.). The yield was 40%. In addition, the ¹H-NMR spectrum data is also shown below.

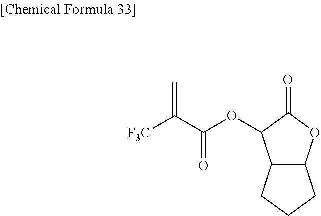 [SMILES: C=C(C(=O)OC1C(=O)OC2CCCC21)C(F)(F)F]

### Spectral Data

¹H-NMR (DMSO-d₆) δ6.93 (s, 1H), 6.64 (s, 1H), 5.75 (m, 1H), 5.04 (t, 1H), 3.15 (m, 1H), 1.85 (m, 2H), 1.60 (m, 4H)

### Example 4 (Preparation of Resin A)

113.33 g of propylene glycol monomethyl ether acetate and 113.33 g of methyl ethyl ketone were introduced into a round bottom flask equipped with a reflux tube, a stirrer, and a 3-way cock under nitrogen atmosphere, and the temperature was maintained at 80° C. While stirring, a mixture solution of 22.5 g (0.11 mol) of the monomer A, 27.5 g (0.11 mol) of 1-(adamantan-1-yl)-1-methylethyl methacrylate (monomer D), 3.1 g of dimethyl-2,2′-azobis isobutyrate (available from Wako Pure Chemical Industries, Ltd., trade name “V-601”), 28.33 g of propylene glycol monomethyl ether acetate, and 28.33 g of methyl ethyl ketone, was added dropwise thereto at a constant rate over a period of 5 hours. After completion of dropwise addition, stirring of the reaction solution was continued for another 2 hours.

After the completion of the polymerization reaction, the reaction solution was added dropwise, while stirring, into a mixed solution (25° C.) of an amount ten-times the amount of the reaction solution, the mixed solution being a 9:1 ratio (weight ratio) of heptane and ethyl acetate. The resulting precipitate was filtered off and dried under reduced pressure, and 42.2 g of the desired polymer was obtained. The recovered polymer was analyzed through GPC, and the Mw (weight average molecular weight) was 10500 and the molecular weight distribution (Mw/Mn) was 1.80.

### Example 5 (Preparation of Resin B)

113.33 g of propylene glycol monomethyl ether acetate and 113.33 g of methyl ethyl ketone were introduced into a round bottom flask equipped with a reflux tube, a stirrer, and a 3-way cock under nitrogen atmosphere, and the temperature was maintained at 80° C. While stirring, a mixture solution of 18.9 g (0.11 mol) of the monomer B, 6.4 g (0.03 mol) of 3-hydroxyadamantan-1-yl methacrylate (monomer E), 24.7 g (0.14 mol) of 1-ethylcyclopentan-1-yl methacrylate (monomer F), 5.9 g of dimethyl-2,2′-azobis isobutyrate (available from Wako Pure Chemical Industries, Ltd., trade name “V-601”), 28.33 g of propylene glycol monomethyl ether acetate, and 28.33 g of methyl ethyl ketone, was added dropwise thereto at a constant rate over a period of 5 hours. After completion of dropwise addition, stirring of the reaction solution was continued for another 2 hours.

After the completion of the polymerization reaction, the reaction solution was added dropwise, while stirring, into a mixed solution (25° C.) of an amount ten-times the amount of the reaction solution, the mixed solution being a 9:1 ratio (weight ratio) of heptane and ethyl acetate. The resulting precipitate was filtered off and dried under reduced pressure, and 36.0 g of the desired polymer was obtained. The recovered polymer was analyzed through GPC, and the Mw (weight average molecular weight) was 7200 and the molecular weight distribution (Mw/Mn) was 1.70.

### Example 6 (Preparation of Resin C)

113.33 g of propylene glycol monomethyl ether acetate and 113.33 g of methyl ethyl ketone were introduced into a round bottom flask equipped with a reflux tube, a stirrer, and a 3-way cock under nitrogen atmosphere, and the temperature was maintained at 80° C. While stirring, a mixture solution of 25.1 g (0.10 mol) of the monomer C, 24.9 g (0.10 mol) of 1-(adamantan-1-yl)-1-methylethyl methacrylate (monomer D), 3.1 g of dimethyl-2,2′-azobis isobutyrate (available from Wako Pure Chemical Industries, Ltd., trade name “V-601”), 28.33 g of propylene glycol monomethyl ether acetate, and 28.33 g of methyl ethyl ketone, was added dropwise thereto at a constant rate over a period of 5 hours. After completion of dropwise addition, stirring of the reaction solution was continued for another 2 hours.

After the completion of the polymerization reaction, the reaction solution was added dropwise, while stirring, into a mixed solution (25° C.) of an amount ten-times the amount of the reaction solution, the mixed solution being a 9:1 ratio (weight ratio) of heptane and ethyl acetate. The resulting precipitate was filtered off and dried under reduced pressure, and 42.8 g of the desired polymer was obtained. The recovered polymer was analyzed through GPC, and the Mw (weight average molecular weight) was 10200 and the molecular weight distribution (Mw/Mn) was 1.85.

### Comparative Example 1 (Preparation of Resin D)

113.33 g of propylene glycol monomethyl ether acetate and 113.33 g of methyl ethyl ketone were introduced into a round bottom flask equipped with a reflux tube, a stirrer, and a 3-way cock under nitrogen atmosphere, and the temperature was maintained at 80° C. While stirring, a mixture solution of 22.2 g (0.11 mol) of 2-oxabicyclo[3.3.0]octan-3-on-4-yl methacrylate (monomer G), 27.8 g (0.11 mol) of 1-(adamantan-1-yl)-1-methylethyl methacrylate (monomer D), 2.1 g of dimethyl-2,2′-azobis isobutyrate (available from Wako Pure Chemical Industries, Ltd., trade name “V-601”), 28.33 g of propylene glycol monomethyl ether acetate, and 28.33 g of methyl ethyl ketone, was added dropwise thereto at a constant rate over a period of 5 hours. After completion of dropwise addition, stirring of the reaction solution was continued for another 2 hours.

After the completion of the polymerization reaction, the reaction solution was added dropwise, while stirring, into a mixed solution (25° C.) of an amount ten-times the amount of the reaction solution, the mixed solution being a 9:1 ratio (weight ratio) of heptane and ethyl acetate. The resulting precipitate was filtered off and dried under reduced pressure, and 45.0 g of the desired polymer was obtained. The recovered polymer was analyzed through GPC, and the Mw (weight average molecular weight) was 10000 and the molecular weight distribution (Mw/Mn) was 1.84.

### Comparative Example 2 (Preparation of Resin E)

113.33 g of propylene glycol monomethyl ether acetate and 113.33 g of methyl ethyl ketone were introduced into a round bottom flask equipped with a reflux tube, a stirrer, and a 3-way cock under nitrogen atmosphere, and the temperature was maintained at 80° C. While stirring, a mixture solution of 18.6 g (0.11 mol) of 2-oxotetrahydrofuran-3-yl methacrylate (monomer H), 6.5 g (0.03 mol) of 3-hydroxyadamantan-1-yl methacrylate (monomer E), 24.9 g (0.14 mol) of 1-ethylcyclopentan-1-yl methacrylate (monomer F), 4.1 g of dimethyl-2,2′-azobis isobutyrate (available from Wako Pure Chemical Industries, Ltd., trade name “V-601”), 28.33 g of propylene glycol monomethyl ether acetate, and 28.33 g of methyl ethyl ketone, was added dropwise thereto at a constant rate over a period of 5 hours. After completion of dropwise addition, stirring of the reaction solution was continued for another 2 hours.

After the completion of the polymerization reaction, the reaction solution was added dropwise, while stirring, into a mixed solution (25° C.) of an amount ten-times the amount of the reaction solution, the mixed solution being a 9:1 ratio (weight ratio) of heptane and ethyl acetate. The resulting precipitate was filtered off and dried under reduced pressure, and 39.8 g of the desired polymer was obtained. The recovered polymer was analyzed through GPC, and the Mw (weight average molecular weight) was 7400 and the molecular weight distribution (Mw/Mn) was 1.72.

The resin produced in Example 4 above had polymerization units represented by the following formulas.

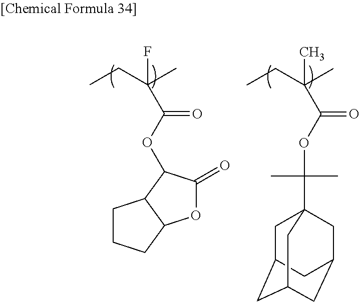

The resin produced in Example 5 above had polymerization units represented by the following formulas.

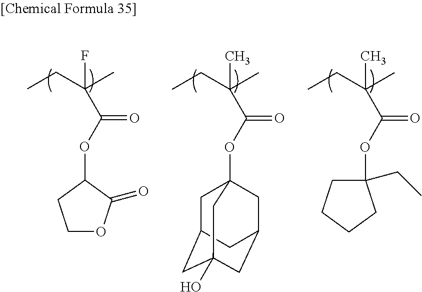

The resin produced in Example 6 above had polymerization units represented by the following formulas.

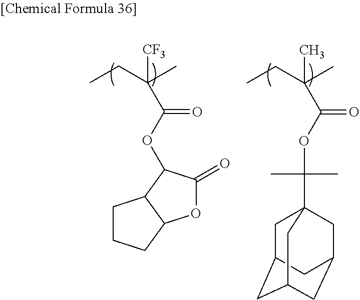

The resin produced in Comparative Example 1 had polymerization units represented by the following formulas.

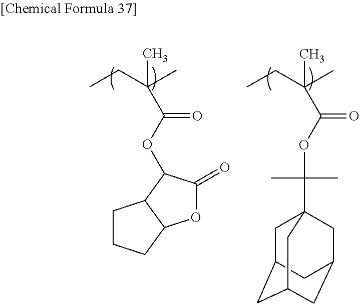

The resin produced in Comparative Example 2 had polymerization units represented by the following formulas.

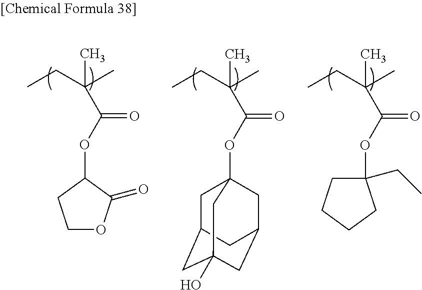

Film Thickness Measurement Prior to Contact with Alkaline Developing Solution

The resins A to E obtained in Examples 4 to 6 and Comparative Examples 1 and 2 were each dissolved in propylene glycol monomethyl ether acetate such that the solid content concentration was 10%, and respective resin solutions were prepared. Each resin solution was applied onto a 10 cm silicon wafer by spin coating and pre-baked at 100° C. for 60 seconds on a hot plate to form a resist resin film. Half of the silicon wafer was immersed in an aqueous solution of 2.38 mass % tetramethylammonium hydroxide (hereinafter, “alkaline developing solution”) for 120 seconds, after which the film thicknesses of the immersed part and the non-immersed part were measured using an atomic force microscope (AFM).

### Evaluation of Swelling Resistance

The film thickness increase rate “Z (%)” before and after immersion in the alkaline developing solution was calculated using the following equation, where the film thickness of the immersed part is denoted as “X (nm)”, and the film thickness of the non-immersed part is denoted as “Y (nm)”,

Z(%)=(Y−X)×100/X

TABLE 1

| | | | | | | | | | Weight | Molecular | Film | | Membrane |
|---|---|---|---|---|---|---|---|---|---|---|---|---|---|
| | | | | | | | | | average | weight | thickness | | thickness |
| | Monomer (mol %) | | | | | | | | molecular | distribution | (nm) | | increase |
| | A | B | C | D | E | F | G | H | weight (Mw) | (Mw/Mn) | X | Y | rate (%) |
| Example 4 | 50 | | | 50 | | | | | 10500 | 1.8 | 146 | 146 | 0 |
| Example 5 | | 40 | | | 10 | 50 | | | 7200 | 1.7 | 138 | 138 | 0 |
| Example 6 | | | 50 | 50 | | | | | 10200 | 1.85 | 143 | 143 | 0 |
| Comparative | | | | 50 | | | 50 | | 10000 | 1.84 | 145 | 160 | 10 |
| Example 1 | | | | | | | | | | | | | |
| Comparative | | | | | 10 | 50 | | 40 | 7400 | 1.72 | 125 | 133 | 6 |
| Example 2 | | | | | | | | | | | | | |

As can be understood from the evaluation results, the photoresist resin of the present invention (Examples 4 to 6) exhibited excellent swelling resistance to the alkaline developing solution. Therefore, it is expected that the photoresist resin of the present invention has excellent resist performance.

1. A photoresist resin comprising a polymerization unit represented by Formula (Y): 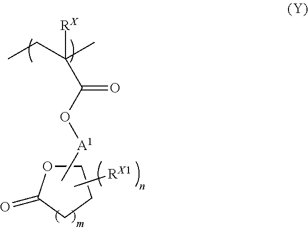
where R^{X} denotes a halogen atom or an alkyl group having from 1 to 6 carbon atoms substituted with a halogen atom; A¹ denotes a single bond or a linking group, and when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

2. The photoresist resin according to claim 1, comprising at least one polymerization unit selected from the group consisting of a polymerization unit represented by Formula (Y1): 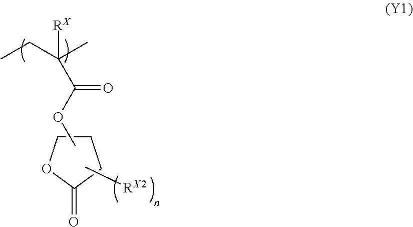
where R^{X} denotes a halogen atom or an alkyl group having from 1 to 6 carbon atoms substituted with a halogen atom; R^{X2} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X2} may be the same or different and may be bonded to each other to form a ring); and
a polymerization unit represented by Formula (Y2): 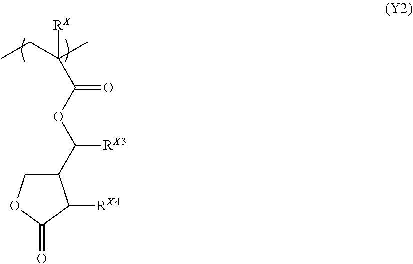
where R^{X} denotes a halogen atom or an alkyl group having from 1 to 6 carbon atoms substituted with a halogen atom; R^{X3} and R^{X4} may be the same or different, and denote a hydrogen atom, an alkyl group having from 1 to 6 carbon atoms, or an alkenyl group having from 2 to 6 carbon atoms, and R^{X3} and R^{X4} may be bonded to each other to form a ring.

3. The photoresist resin according to claim 2,
wherein the polymerization unit represented by Formula (Y1) is a polymerization unit represented by Formula (Y3): 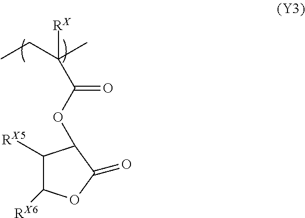
where R^{X} denotes a halogen atom or an alkyl group having from 1 to 6 carbon atoms substituted with a halogen atom; R^{X5} and R^{X6} may be the same or different, and denote a hydrogen atom, an alkyl group having from 1 to 6 carbon atoms, or an alkenyl group having from 2 to 6 carbon atoms, and R^{X5} and R^{X6} may be bonded to each other to form a ring; or
a polymerization unit represented by Formula (Y4): 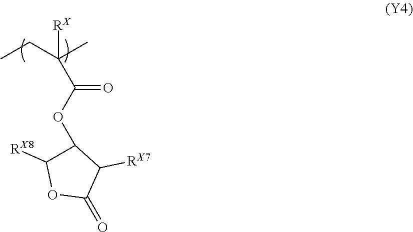
where R^{X} denotes a halogen atom or an alkyl group having from 1 to 6 carbon atoms substituted with a halogen atom; R^{X7} and R^{X8} may be the same or different, and denote a hydrogen atom, an alkyl group having from 1 to 6 carbon atoms, or an alkenyl group having from 2 to 6 carbon atoms.

4. The photoresist resin according to claim 1,
wherein the polymerization unit represented by Formula (Y) is derived from a monomer selected from the group consisting of monomers represented by following Formulas:

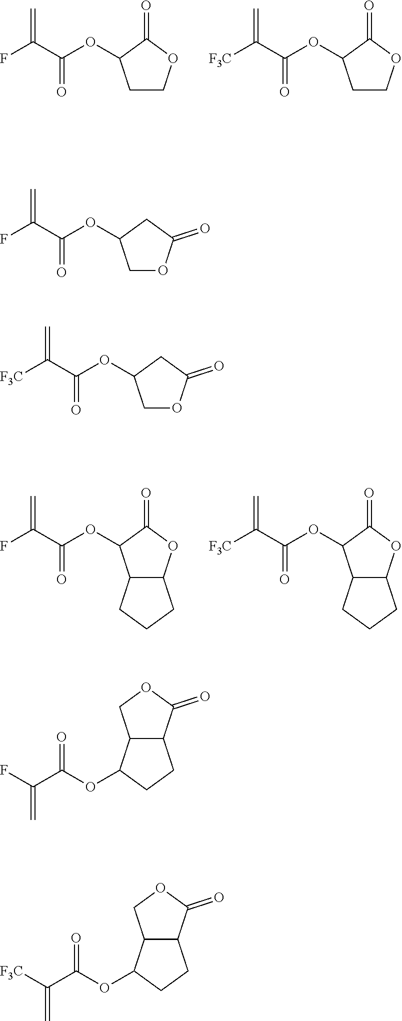

5. The photoresist resin according to claim 1,
wherein the polymerization unit represented by Formula (Y) is derived from a monomer selected from the group consisting of monomers represented by following Formulas:

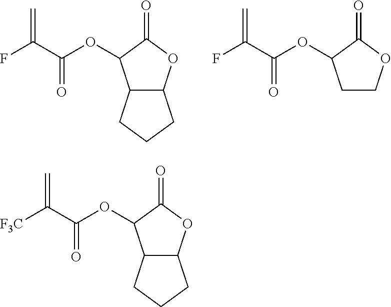

6. The photoresist resin according to claim 1, comprising at least one polymerization unit selected from the group consisting of polymerization units represented by Formulas (a1) to (a4): 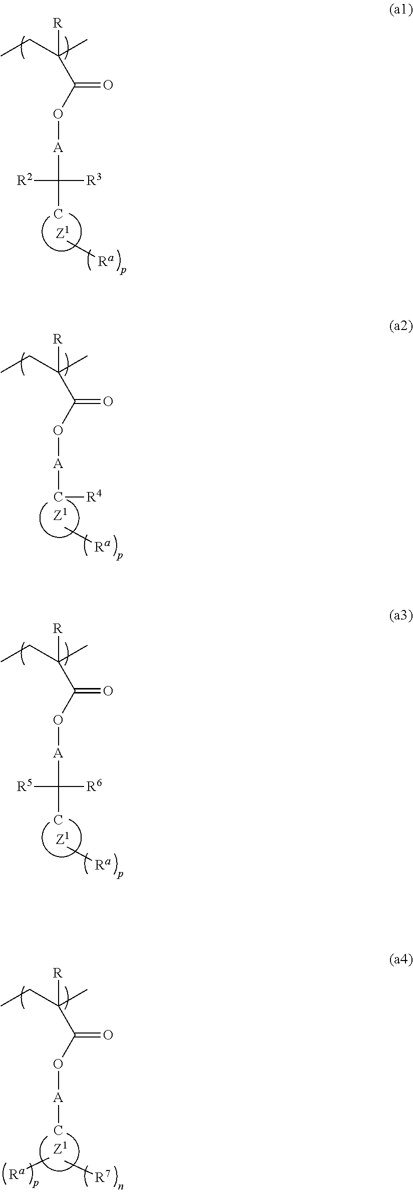
where R denotes a hydrogen atom, a halogen atom, or an alkyl group which has from 1 to 6 carbon atoms and may have a halogen atom; A denotes a single bond or a linking group; R² to R⁴ may be the same or different and denote an alkyl group which has from 1 to 6 carbon atoms and may have a substituent; R² and R³ may be bonded to each other to form a ring; R⁵ and R⁶ may be the same or different and denote a hydrogen atom or an alkyl group which has from 1 to 6 carbon atoms and may have a hydrogen atom or a substituent; R⁷ denotes a —COOR^{c} group, and the R^{c} denotes a tertiary hydrocarbon group, a tetrahydrofuranyl group, a tetrahydropyranyl group, or an oxepanyl group, each of which may have a substituent; n denotes an integer from 1 to 3; R^{a} is a substituent bonded to a ring Z¹, and may be the same or different, and denotes an oxo group, an alkyl group, a hydroxy group that may be protected by a protecting group, a hydroxyalkyl group that may be protected by a protecting group, or a carboxy group that may be protected by a protecting group; p denotes an integer from 0 to 3; and the ring Z¹ denotes an alicyclic hydrocarbon ring having from 3 to 20 carbon atoms.

7. The photoresist resin according to claim 1, comprising at least one polymerization unit selected from the group consisting of polymerization units represented by Formulas (b1) to (b5) (excluding polymerization units corresponding to the polymerization unit represented by Formula (Y)): 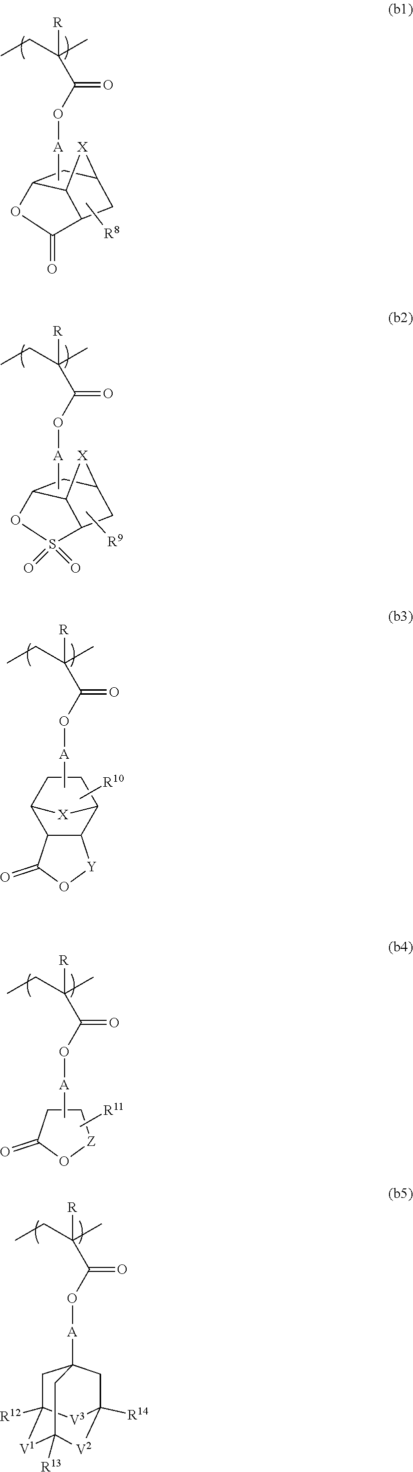
where R denotes a hydrogen atom, a halogen atom, or an alkyl group which has from 1 to 6 carbon atoms and may have a halogen atom; A denotes a single bond or a linking group; X denotes no bond, a methylene group, an ethylene group, an oxygen atom, or a sulfur atom; Y denotes a methylene group or a carbonyl group; Z denotes a divalent organic group; V¹ to V³ may be the same or different, and denote —CH₂—, [—C(═O)—], or [—C(═O)—O—], with a proviso that at least one of V¹ to V³ is [—C(═O)—O—]; and R⁸ to R¹⁴ may be the same or different, and denote a hydrogen atom, a fluorine atom, an alkyl group that may have a fluorine atom, a hydroxy group that may be protected by a protecting group, a hydroxyalkyl group that may be protected by a protecting group, a carboxy group that may be protected by a protecting group, or a cyano group.

8. The photoresist resin according to claim 1, comprising a polymerization unit represented by Formula (c1): 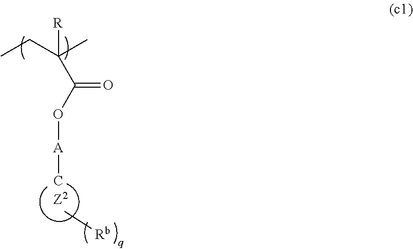
where R denotes a hydrogen atom, a halogen atom, or an alkyl group which has from 1 to 6 carbon atoms and may have a halogen atom; A denotes a single bond or a linking group; R^{b} denotes a hydroxy group that may be protected by a protecting group, a hydroxyalkyl group that may be protected by a protecting group, a carboxy group that may be protected by a protecting group, or a cyano group; q denotes an integer from 1 to 5; and the ring Z² denotes an alicyclic hydrocarbon ring having from 6 to 20 carbon atoms.

9. A photoresist resin composition comprising at least the photoresist resin described in claim 1 and a radiation sensitive acid generating agent.

10. A pattern forming method comprising at least applying the photoresist resin composition described in claim 9 to a substrate to form a coating film, exposing the coating film, and subsequently subjecting the coating film to alkali dissolution.

11. A monomer represented by Formula (X): 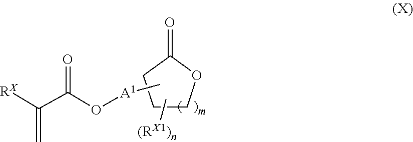
where R^{X} denotes a halogen atom or an alkyl group having from 1 to 6 carbon atoms substituted with a halogen atom; A¹ denotes a single bond or a linking group, and when A¹ denotes a linking group, A¹ and R^{X1} may be bonded to each other to form a ring; R^{X1} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X1} may be the same or different and may be bonded to each other to form a ring; and m denotes an integer from 1 to 4.

12. The monomer according to claim 11, the monomer being a monomer represented by Formula (X1): 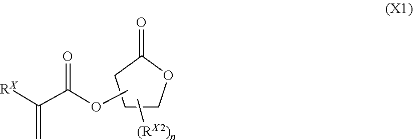
where R^{X} denotes a halogen atom or an alkyl group having from 1 to 6 carbon atoms substituted with a halogen atom; R^{X2} denotes a hydrogen atom, an alkyl group having from 1 to 6 carbon atoms, or an alkenyl group having from 2 to 6 carbon atoms; n denotes an integer from 0 to 5, and when n is 2 or greater, the multiple R^{X2} may be the same or different and may be bonded to each other to form a ring;
or a monomer represented by Formula (X2): 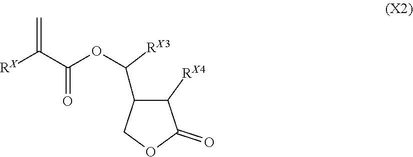
where R^{X} denotes a halogen atom or an alkyl group having from 1 to 6 carbon atoms substituted with a halogen atom; R^{X3} and R^{X4} may be the same or different, and denote a hydrogen atom, an alkyl group having from 1 to 6 carbon atoms, or an alkenyl group having from 2 to 6 carbon atoms, and R^{X3} and R^{X4} may be bonded to each other to form a ring.

13. The monomer according to claim 12, wherein the monomer represented by Formula (X1) is a monomer represented by Formula (X3): 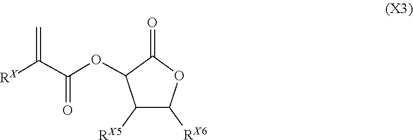
where R^{X} denotes a halogen atom or an alkyl group having from 1 to 6 carbon atoms substituted with a halogen atom; R^{X5} and R^{X6} may be the same or different, and denote a hydrogen atom, an alkyl group having from 1 to 6 carbon atoms, or an alkenyl group having from 2 to 6 carbon atoms, and R^{X5} and R^{X6} may be bonded to each other to form a ring; or
a monomer represented by Formula (X4): 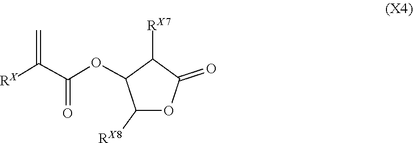
where R^{X} denotes a halogen atom or an alkyl group having from 1 to 6 carbon atoms substituted with a halogen atom; R^{X7} and R^{X8} may be the same or different, and denote a hydrogen atom, an alkyl group having from 1 to 6 carbon atoms, or an alkenyl group having from 2 to 6 carbon atoms.

14. The monomer according to claim 11,
wherein the monomer represented by Formula (Y) is selected from the group consisting of monomers represented by following Formulas:

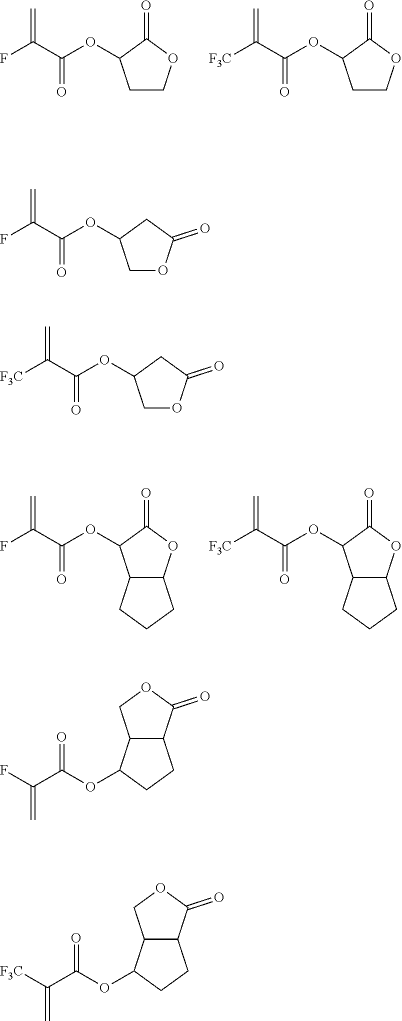

15. The monomer according to claim 11,
wherein the monomer represented by Formula (Y) is selected from the group consisting of monomers represented by following Formulas: [chemical structure]
